(19) United States
(12) Patent Application Publication
(10) Pub. No.: US 2014/0216555 A1
(43) Pub. Date: Aug. 7, 2014

(54) METAL CHALCOGENIDES AND METHODS OF MAKING AND USING SAME

(71) Applicants: Eray S. Aydil, Minneapolis, MN (US); David J. Norris, Zurich (CH); Ankur Khare, Minneapolis, MN (US); Andrew Wilke Wills, Wilmington, DE (US); Banu Selin Tosun, Minneapolis, MN (US)

(72) Inventors: Eray S. Aydil, Minneapolis, MN (US); David J. Norris, Zurich (CH); Ankur Khare, Minneapolis, MN (US); Andrew Wilke Wills, Wilmington, DE (US); Banu Selin Tosun, Minneapolis, MN (US)

(73) Assignee: REGENTS OF THE UNIVERSITY OF MINNESOTA, Saint Paul, MN (US)

(21) Appl. No.: 13/980,404

(22) PCT Filed: Jan. 20, 2012
(86) PCT No.: PCT/US12/21991

§ 371 Date: Apr. 14, 2014

Related U.S. Application Data
(60) Provisional application No. 61/434,854, filed on Jan. 21, 2011.

(51) Int. Cl. H01L 31/032; H01L 31/18

(52) U.S. Cl. CPC H01L 31/0326; H01L 31/1864
USPC 136/264; 252/519.14; 438/488

(57) ABSTRACT

Metal chalcogenides, and methods of making and using metal chalcogenides, are disclosed herein. Metal chalcogenides can be prepared by heating suitable copper, zinc, and/or tin compounds selected from the group consisting of chalcogenocarbamates, dichalcogenocarbamates, mercaptides, thiiocarbonates, trithiocarbonates, and combinations thereof (e.g., copper, zinc, and/or tin dichalcogenocarbamates) under conditions effective to form metal can be used, for example, to prepare solar cells.

This application claims the benefit of U.S. Provisional Application No. 61/434,854, filed Jan. 21, 2011, which is hereby incorporated by reference in its entirety.

### GOVERNMENT FUNDING

The present invention was made with government support under Agency Grant Nos. DMR-0819885 and CBET-0931145 from the National Science Foundation MRSEC. The Government has certain rights in this invention.

### BACKGROUND

Solar cells manufactured using one to three micron thin films of light absorbing semiconductors cost less than the solar cells manufactured using thicker (100-500 micron) silicon wafers because thin films use less material and, in general, can be manufactured at lower temperatures. The leading thin-film solar cell technologies are distinguished based on the light absorbing material and include (1) amorphous silicon thin film solar cells, (2) cadmium telluride (CdTe) thin film solar cells, and (3) copper indium gallium diselenide (CIGS) thin film solar cells. However, properties and characteristics of these light absorbing materials have hampered the development of solar cells based on these technologies, as further discussed below.

For example, amorphous silicon suffers from instability and low efficiency when exposed to sunlight, and the resulting stabilized efficiency for such solar cell modules rarely exceeds 10%.

CIGS has been demonstrated to have high laboratory efficiencies (20%). However CIGS thin films are difficult to deposit uniformly on large scale; they suffer from instability when exposed to moisture; and they contain indium, which is a scarce material. Furthermore, indium prices have increased by as much as a factor of eight in the last decade due to demand in electronics industry for this scarce metal.

CdTe is currently an important thin film solar cell technology. The cost of making CdTe solar cells has been lowered significantly in recent years. Although CdTe solar cells are simple and inexpensive to make, use of Cd necessitates cradle-to-grave recycling. Moreover, tellurium is a rare element.

Finally, limited tellurium and indium supplies may limit the annual production levels of both CdTe and CIGS solar cells, preventing adequate production levels to reach terawatt levels of solar cell power production.

Thus, there remains a need in the art for convenient methods using existing and/or new materials for making efficient solar cells.

### SUMMARY

Thin films of copper zinc tin sulphide (Cu₂ZnSnS₄; often abbreviated as CZTS) and copper zinc tin selenide (Cu₂ZnSnSe₄; often abbreviated as CZTSe) are emerging as potential alternatives to CdTe and CIGS as a solar cell material that contains only abundant and nontoxic elements. Overall power conversion efficiencies of 6.7% and nearly 9.6% were reached with solar cells based on thin films of CZTS and CZTSe, respectively. CZTS has been made by depositing copper, zinc and tin metals on a substrate using various physical deposition methods (sputtering, evaporation, etc.), and sulfurizing the resulting film at temperatures ranging from 400-700° C.

CZTS solar cells have been fashioned after the structure of the CIGS solar cells in which the CIGS absorber layer has been replaced with CZTS film. Similar to CIGS solar cells, CZTS has been deposited on molybdenum-coated soda-lime glass using one of the methods described above. Following, CZTS films have been coated with a thin cadmium sulfide (CdS) buffer layer, typically through chemical bath deposition (CBD). Next, Al doped ZnO or other transparent conducting oxide films have been deposited by sputtering.

However, there remains a need for new methods for making CZTS, CZTSe and CZTSSe, and new constructions for solar cells containing these materials. Disclosed herein are methods for making CZTS, CZTSe and CZTSSe in the form of, for example, colloidal dispersions (“inks”), solutions, and/or thin films.

In one aspect, the present disclosure provides a method of preparing a metal chalcogenide (e.g., a copper zinc tin chalcogenide). The method includes heating components including: at least one copper, zinc, and/or tin compound selected from the group consisting of chalcogenocarbamates, dichalcogenocarbamates, mercaptides, thiolates, dithiolates, thiocarbonates, dithiocarbonates, trithiocarbonates, and combinations thereof. Heating includes conditions effective to form a compound of the formula Cu_{2+x+z}Zn₁₋ₓSn_{1-z}A₄, wherein A represents one or more chalcogens (e.g. sulfur, selenium, or a combination thereof); −1≦x≦1; −1≦z≦1; and with the proviso that when x=z they are not equal to 1. Preferably the copper, zinc, and/or tin compounds are heated in the substantial absence of oxygen.

Exemplary copper dichalcogenocarbamates include those of the formula Cu²⁺(⁻A-(A)C—NR¹R²)₂, wherein each R¹ and R² independently represents H or an organic group in which R¹ and R² can optionally be joined to form one or more rings; and each A independently represents a chalcogen.

Exemplary zinc dichalcogenocarbamates include those of the formula Zn²⁺(⁻A-(A)C—NR¹R²)₂, wherein each R¹ and R² independently represents H or an organic group in which R¹ and R² can optionally be joined to form one or more rings; and each A independently represents a chalcogen.

Exemplary tin dichalcogenocarbamates include those of the formula Sn⁴⁺(⁻A-(A)C—NR¹R²)₄, wherein each R¹ and R² independently represents H or an organic group in which R¹ and R² can optionally be joined to form one or more rings; and each A independently represents a chalcogen.

Exemplary metal chalcogenides that can be prepared by such methods include, but are not limited to, those of the formulas Cu_{2+z}ZnSn_{1-z}S_{y}Se_{4-y}; Cu₂ZnSnS_{y}Se_{4-y}; Cu₃ZnS_{y}Se_{4-y}; CuZnSn₂S_{y}Se_{4-y}; Cu_{1+z}Zn₂Sn_{1-z}S_{y}Se_{4-y}; CuZn₂SnS_{y}Se_{4-y}; Cu₂Zn₂S_{y}Se_{4-y}; Zn₂Sn₂S_{y}Se_{4-y}; Cu_{3+z}Sn_{1-z}S_{y}Se_{4-y}; Cu₃SnS_{y}Se_{4-y}; Cu₂Sn₂S_{y}Se_{4-y}; Cu₂₊ₓZn₁₋ₓSnS_{y}Se_{4-y}; Cu₃₊ₓZn₁₋ₓS_{y}Se_{4-y}; and Cu₁₊ₓZn₁₋ₓSn₂S_{y}Se_{4-y}, wherein x and z are as defined above, and 0≦y≦4.

In one embodiment, the components can be heated in a solvent at a temperature of 125° C. to 300° C., optionally in the presence of an amine (e.g., oleylamine), to form the metal chalcogenide in the form of nanocrystals. Optionally, the nanocrystals can be coated (e.g., as a colloidal dispersion or solution) on a substrate and heated to form a film of the metal chalcogenide. Colloidal dispersions or solutions of such nanocrystals are also disclosed herein.

In another embodiment, the components can be applied to a substrate and heated at a temperature of 150° C. to 900° C., optionally in the presence of an amine (e.g., oleylamine), to form a film of the metal chalcogenide.

In another aspect, the present disclosure provides solar cells, and methods of making solar cells, that include a substrate and one or more copper zinc tin chalcogenide layers as disclosed herein. In certain embodiments the copper zinc tin chalcogenide is copper-deficient and is of the formula Cu₂₊ₓZn₁₋ₓSn S_{y}Se_{4-y}, wherein: 0≦y≦4; and −1<x<0. In other certain embodiments, the copper zinc tin chalcogenide is copper-rich and is of the formula Cu₂₊ₓZn₁₋ₓSn S_{y}Se_{4-y}, wherein: 0≦y≦4; and 0<x<1. In some embodiments the solar cells include one or more copper-deficient copper zinc tin chalcogenide layers and one or more copper-rich copper zinc tin chalcogenide layers. Optionally, the solar cells can further include a zinc sulfide, a tin oxide, and/or a zinc oxide buffer layer over at least one metal chalcogenide layer or layers.

In preferred embodiments, at least some of the methods of making and using metal chalcogenides disclosed herein can overcome at least some of the problems encountered by methods known in the art. For example, in certain embodiments, the methods disclosed herein for making metal chalcogenides employ commonly available materials and can preferably reduce undesirable wastes. For another example, in certain embodiments, the solar cells disclosed herein can reduce or eliminate at least some undesirable materials used in the construction of the cells.

### DEFINITIONS

Unless otherwise specified, “a,” “an,” “the,” and “at least one” are used interchangeably and mean one or more than one.

As used herein, the term “comprising,” which is synonymous with “including” or “containing,” is inclusive, open-ended, and does not exclude additional unrecited elements or method steps.

The above brief description of various embodiments of the present invention is not intended to describe each embodiment or every implementation of the present invention. Rather, a more complete understanding of the invention will become apparent and appreciated by reference to the following description and claims in view of the accompanying drawings. Further, it is to be understood that other embodiments may be utilized and structural changes may be made without departing from the scope of the present invention.

### BRIEF DESCRIPTION OF THE DRAWINGS

FIG. 1 is a graphical representation of differential scanning calorimetry data for exemplary copper, zinc, and tin diethyl dithiocarbamates.

FIG. 2 is a graphical representation of thermogravimetric analysis (TGA) data for exemplary copper, zinc and tin diethyl dithiocarbamates.

FIG. 3 is a schematic illustration showing the two exemplary types of films and solar cells that can be formed from dispersions of nanocrystals.

FIG. 4 is a schematic illustration of an exemplary CZTS thin film solar cell.

FIG. 5 is a reproduction of a digital photograph of exemplary metal dithiocarbamate solutions {Cu(dedc)₂, Zn(dedc)₂ and Sn(dedc)₄} that may be used for forming CZTS films.

FIG. 6 is a schematic illustration of a sequence of exemplary steps that can be used to deposit CZTS films from a solution of metal complexes.

FIG. 7 is a graphical representation illustrating the theoretical maximum efficiency of a thin film solar cell as a function of the band gap of the semiconductor used for absorbing the light. The theoretical efficiencies for CIGS, silicon, CdTe, and CZTS are marked for comparison. Based on band gap and optical absorption, CZTS has approximately the same maximum theoretical efficiency as the leading state-of-the-art solar cell technologies.

FIG. 8 is a graphical representation of the optical absorption spectrum of an exemplary colloidal dispersion of approximately 10 nanometer diameter CZTS nanocrystals. The inset shows the Tauc plot where square of the product of the absorption coefficient and energy is plotted versus the energy. The band gap can be determined by extrapolating the Tauc plot to zero absorption.

FIG. 9 is a graphical representation of the optical absorption spectrum of different diameter exemplary nanocrystals. The rising edge of the spectrum has been marked with an arrow for clarity. The inset shows the Tauc plot for the corresponding absorbance curves. The spectra are shifted along the y-axis for clarity. The absorptions for each size asymptote to zero at the far right where the wavelength is greater than 1000 nanometers.

FIG. 10 is a graphical representation of the Raman spectra obtained from different size exemplary nanocrystals.

FIG. 11 is a schematic drawing of an exemplary apparatus that can be used to prepare exemplary CZTS nanocrystals.

FIG. 12 is a reproduction of a digital photograph of exemplary CZTS nanocrystals dispersed in toluene (i.e., CZTS nanocrystal ink.)

FIG. 13 is a graphical representation of the X-ray diffraction data from different size exemplary nanocrystals. The stick reference powder XRD pattern is that for the CZTS Kesterite structure (JCPDS no. 26-0575). The particle sizes determined from the width of the (112) diffraction peak width are indicated next to each pattern.

FIG. 14 is an illustration showing transmission electron microscope images of different size exemplary CZTS nanocrystals: a) 2 nanometers; b) 2.5 nanometers; c) 5 nanometers; and d) 7 nanometers. The scale bars are all 2 nanometers in length.

FIG. 15 is a graphical representation showing measured (top curve) and calculated (bottom curve) X-ray diffraction data for 10 nanometer diameter exemplary nanocrystals that were prepared using copper diethyldithiocarbamate {Cu(S₂CN(C₂H₅)₂)₂; Cu(dedc)₂}, zinc undecyldithiocarbamate {Zn(S₂CNH(C₁₁H₂₃))₂; Zn(undc)₂} and tin dimethyldithiocarbamate {Sn(S₂CN(CH₃)₂)₄; Sn(dmdc)₂}.

FIG. 16 is an illustration showing the transmission electron microscope image of a larger, approximately 10 nanometer diameter, exemplary CZTS nanocrystal. Various atomic planes are also shown and their spacing are consistent with the CZTS crystal structure.

FIG. 17 is an illustration of selected area electron diffraction showing diffraction rings from various CZTS atomic planes.

FIG. 18 is a graphical representation of the Raman spectrum of an exemplary CZTS film formed by annealing CZTS nanocrystals at 400° C. for 90 minutes under nitrogen atmosphere.

FIG. 19 is a graphical representation of x-ray diffraction data showing the evolution of the structure of a mixture of the metal complexes as the mixture melts and reacts to eventually form CZTS.

FIG. 20 is a graphical representation of x-ray diffraction data showing the evolution of the structure of a film of CZTS nanocrystals upon heating.

### DETAILED DESCRIPTION OF ILLUSTRATIVE EMBODIMENTS

Metal chalcogenides, and methods of making and using metal chalcogenides, are disclosed herein. As used herein, the phrase “metal chalcogenides” is intended to include compounds that include at least one metal cation and at least one chalcogenide anion (e.g., sulfur, selenium, or a combination thereof). As such, the phrase metal chalcogenides can refer to a variety of compounds including, but not limited to, copper chalcogenides, copper zinc chalcogenides, copper tin chalcogenides, zinc tin chalcogenides, and copper zinc tin chalcogenides. Exemplary metal chalcogenides can be represented by the formula Cu_{2+x+z}Zn₁₋ₓSn_{1-z}A₄, wherein A represents one or more chalcogens; −1≦x≦1; −1≦z≦1; and with the proviso that when x=z they are not equal to 1.

Advantageously, the present disclosure provides methods in which metal chalcogenides can be prepared by heating suitable copper, zinc, and/or tin compounds selected from the group consisting of chalcogenocarbamates, dichalcogenocarbamates, mercaptides, thiolates, dithiolates, thiocarbonates, dithiocarbonates, trithiocarbonates, and combinations thereof (e.g., copper, zinc, and/or tin dichalcogenocarbamates) under conditions effective to form metal chalcogenides. For example, a wide variety of dichalcocarbamates can be used to prepare metal chalcogenides. Such dichalcocarbamates can often be prepared and purified by recrystallization according to known methods.

Useful dichalcogenocarbamates can include carbamate groups of the formula ⁻A-(A)C—NR¹R², wherein each R¹ and R² independently represents H or an organic group in which R¹ and R² can optionally be joined to form one or more rings; and each A independently represents a chalcogen (e.g., sulfur, selenium, or a combination thereof). When R¹ and/or R² represent an organic group, preferably the organic group is a carbon-bound (i.e., the bond to the group is to a carbon atom of the organic group) organic group. In certain embodiments, the organic group is an aliphatic group such as a C1-C30 aliphatic group, in some embodiments a C1-C20 aliphatic group. In other certain embodiments, the organic group is a C1-C30 hydrocarbon moiety, and in some embodiments a C1-C20 hydrocarbon moiety.

As used herein, the term “organic group” is used for the purpose of this disclosure to mean a hydrocarbon group that is classified as an aliphatic group, cyclic group, or combination of aliphatic and cyclic groups (e.g., alkaryl and aralkyl groups). In the context of the present disclosure, suitable organic groups for metal chalcogenides or precursors thereof, as described herein, are those that do not interfere with the formation of such chalcogenides. In the context of the present disclosure, the term “aliphatic group” means a saturated or unsaturated linear or branched hydrocarbon group. This term is used to encompass alkyl, alkenyl, and alkynyl groups, for example. The term “alkyl group” means a saturated linear or branched monovalent hydrocarbon group including, for example, methyl, ethyl, n-propyl, isopropyl, tert-butyl, amyl, heptyl, and the like. The term “alkenyl group” means an unsaturated, linear or branched monovalent hydrocarbon group with one or more olefinically unsaturated groups (i.e., carbon-carbon double bonds), such as a vinyl group. The term “alkynyl group” means an unsaturated, linear or branched monovalent hydrocarbon group with one or more carbon-carbon triple bonds. The term “cyclic group” means a closed ring hydrocarbon group that is classified as an alicyclic group, aromatic group, or heterocyclic group. The term “alicyclic group” means a cyclic hydrocarbon group having properties resembling those of aliphatic groups. The term “aromatic group” or “aryl group” means a mono- or polynuclear aromatic hydrocarbon group. The term “heterocyclic group” means a closed ring hydrocarbon in which one or more of the atoms in the ring is an element other than carbon (e.g., nitrogen, oxygen, sulfur, etc.).

As a means of simplifying the discussion and the recitation of certain terminology used throughout this application, the terms “group” and “moiety” are used to differentiate between chemical species that allow for substitution or that may be substituted and those that do not so allow for substitution or may not be so substituted. Thus, when the term “group” is used to describe a chemical substituent, the described chemical material includes the unsubstituted group and that group with nonperoxidic O, N, S, Si, or F atoms, for example, in the chain as well as carbonyl groups or other conventional substituents. Where the term “moiety” is used to describe a chemical compound or substituent, only an unsubstituted chemical material is intended to be included. For example, the phrase “alkyl group” is intended to include not only pure open chain saturated hydrocarbon alkyl substituents, such as methyl, ethyl, propyl, tert-butyl, and the like, but also alkyl substituents bearing further substituents known in the art, such as hydroxy, alkoxy, alkylsulfonyl, halogen atoms, cyano, nitro, amino, carboxyl, etc. Thus, “alkyl group” includes ether groups, haloalkyls, nitroalkyls, carboxyalkyls, hydroxyalkyls, sulfoalkyls, etc. On the other hand, the phrase “alkyl moiety” is limited to the inclusion of only pure open chain saturated hydrocarbon alkyl substituents, such as methyl, ethyl, propyl, tert-butyl, and the like.

For example, useful copper dichalcogenocarbamates can include those of the formula Cu²⁺(⁻A-(A)C—NR¹R²)₂, wherein each R¹ and R² independently represents H or an organic group in which R¹ and R² can optionally be joined to form one or more rings; and each A independently represents a chalcogen (e.g., sulfur, selenium, or a combination thereof). When R¹ and/or R² represent an organic group, preferably the organic group is a carbon-bound (i.e., the bond to the group is to a carbon atom of the organic group) organic group. In certain embodiments, the organic group is an aliphatic group such as a C1-C30 aliphatic group, in some embodiments a C1-C20 aliphatic group. In other certain embodiments, the organic group is a C1-C30 hydrocarbon moiety, and in some embodiments a C1-C20 hydrocarbon moiety. In preferred embodiments, copper dichalcogenocarbamates include those of the formula Cu²⁺(⁻A-(A)C—N(C₂H₅)₂)₂, and each A independently represents a chalcogen (e.g., sulfur, selenium, or a combination thereof). Such preferred copper dichalcogenocarbamates include, but are not limited to, copper complexes of N,N-dimethyldithiocarbamate, N,N-dimethyldiselenocarbamate, N,N-dimethylthioselenocarbamate, N,N-diethyldithiocarbamate, N,N-diethyldiselenocarbamate, N,N-diethylthioselenocarbamate, N-undecyldithiocarbamate, N-undecyldiselenocarbamate, and N-undecylthioselenocarbamate.

For another example, useful zinc dichalcogenocarbamates can include those of the formula Zn²⁺(⁻A-(A)C—NR¹R²)₂, wherein each R¹ and R² independently represents H or an organic group in which R¹ and R² can optionally be joined to form one or more rings; and each A independently represents a chalcogen (e.g., sulfur, selenium, or a combination thereof). When R¹ and/or R² represent an organic group, preferably the organic group is a carbon-bound (i.e., the bond to the group is to a carbon atom of the organic group) organic group. In certain embodiments, the organic group is an aliphatic group such as a C1-C30 aliphatic group, in some embodiments a C1-C20 aliphatic group. In other certain embodiments, the organic group is a C1-C30 hydrocarbon moiety, and in some embodiments a C1-C20 hydrocarbon moiety. Such preferred zinc dichalcogenocarbamates include, but are not limited to, zinc complexes of N,N-dimethyldithiocarbamate, N,N-dimethyldiselenocarbamate, N,N-dimethylthioselenocarbamate, N,N-diethyldithiocarbamate, N,N-diethyldiselenocarbamate, N,N-diethylthioselenocarbamate, N-undecyldithiocarbamate, N-undecyldiselenocarbamate, and N-undecylthioselenocarbamate.

For a further example, useful tin carbamates can include those of the formula Sn⁴⁺(⁻A-(A)C—NR¹R²)₄, wherein each R¹ and R² independently represents H or an organic group in which R¹ and R² can optionally be joined to form one or more rings; and each A independently represents a chalcogen (e.g., sulfur, selenium, or a combination thereof). When R¹ and/or R² represent an organic group, preferably the organic group is a carbon-bound (i.e., the bond to the group is to a carbon atom of the organic group) organic group. In certain embodiments, the organic group is an aliphatic group such as a C1-C30 aliphatic group, in some embodiments a C1-C20 aliphatic group. In other certain embodiments, the organic group is a C1-C30 hydrocarbon moiety, and in some embodiments a C1-C20 hydrocarbon moiety. Such preferred tin dichalcogenocarbamates include, but are not limited to, tin complexes of N,N-dimethyldithiocarbamate, N,N-dimethyldiselenocarbamate, N,N-dimethylthioselenocarbamate, N,N-diethyldithiocarbamate, N,N-diethyldiselenocarbamate, N,N-diethylthioselenocarbamate, N-undecyldithiocarbamate, N-undecyldiselenocarbamate, and N-undecylthioselenocarbamate.

Conditions effective to form metal chalcogenides include heating suitable copper, zinc, and/or tin compounds selected from the group consisting of chalcogenocarbamates, dichalcogenocarbamates, mercaptides, thiolates, dithiolates, thiocarbonates, dithiocarbonates, trithiocarbonates, and combinations thereof (e.g., copper, zinc, and/or tin dichalcogenocarbamates), preferably in the substantial absence of oxygen (e.g., in vaccuo or under an inert atmosphere).

In some embodiments, the copper, zinc, and/or tin compounds selected from the group consisting of chalcogenocarbamates, dichalcogenocarbamates, mercaptides, thiolates, dithiolates, thiocarbonates, dithiocarbonates, trithiocarbonates, and combinations thereof (e.g., copper, zinc, and/or tin dichalcogenocarbamates) can be heated in a solvent (e.g., at a temperature of 125° C. to 300° C.) to form the metal chalcogenide. For certain embodiments, it is believed that the dichalcocarbamates decompose thermally to produce their corresponding sulfides. Properties of the dichalcocarbamates (e.g., melting and decomposition temperatures) depend on the metal, R¹, and R², and can be varied by changing these groups. In certain embodiments, the metal chalcogenide can be precipitated from the solvent in the form of nanocrystals.

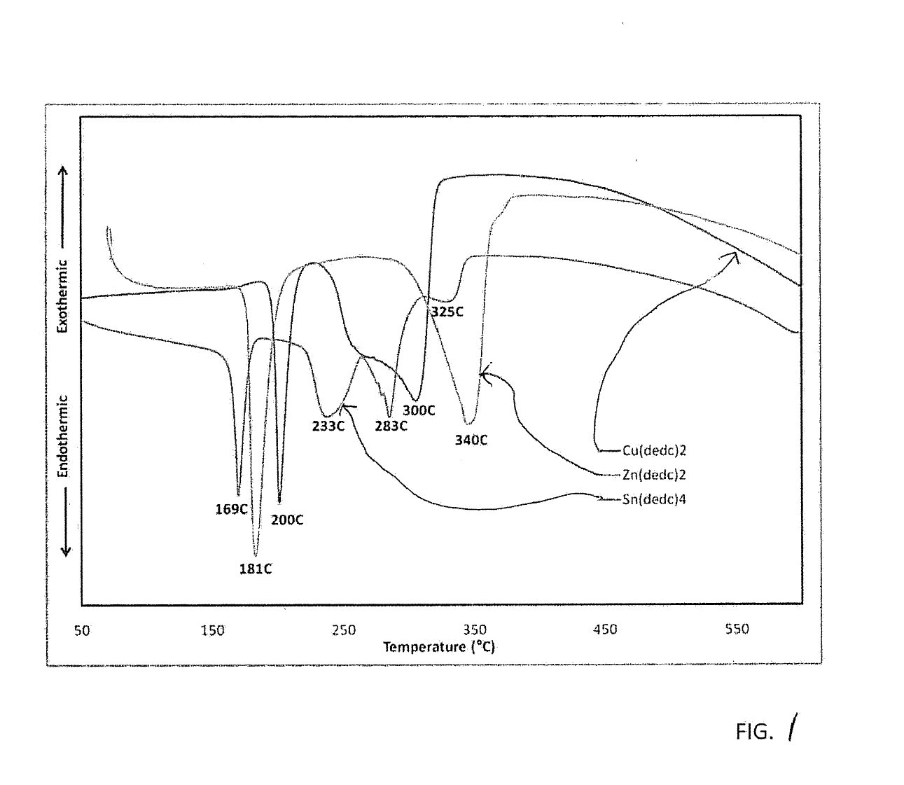

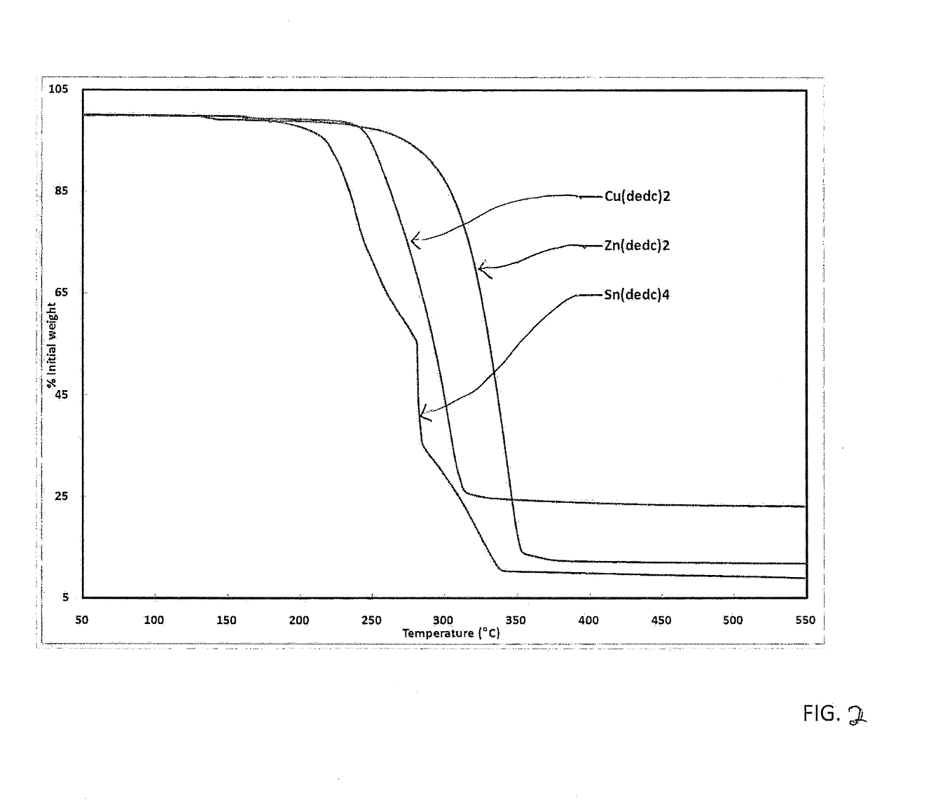

For certain embodiments, when stoichiometric mixtures of copper, zinc, and tin dithiocarbamates are heated together they can decompose together to give CZTS. For example, FIG. 1 and FIG. 2 show the differential scanning calorimetry (DSC) and thermogravimetric analysis (TGA) data for these three CZTS precursors. These figures show that copper, zinc, and tin diethyl dithiocarbamates decompose at 300° C., 340° C., and 233° C., respectively. The sharp endothermic peaks in FIG. 1 around 150-200° C. correspond to melting of the complexes, which indicates that neat solid complexes melt to form liquids before they decompose. The presence of an amine (e.g., oleylamine) can lower the decomposition temperatures of these three complexes to a narrow range; thus, simultaneous decomposition of the copper, zinc, and tin dithiocarbamate complexes can be triggered by injecting oleylamine at temperatures below the individual decomposition temperatures. This method can lead to nucleation and subsequent growth of CZTS nanoparticles.

The amount of oleylamine injected to decompose these complexes can influence the availability of nucleation sites for growth of the nanocrystals. By varying the amount of oleylamine injected and the growth temperature, the average diameter of the nanocrystals can be tuned.

In a typical preparation, the contents of the flask can be heated to the desired temperature and a specific volume of oleylamine can be injected into this mixture. The nanocrystal size can be tuned by changing the temperature at which olelyamine is injected and the amount of oleylamine. For example, to prepare 2 nanometer diameter nanocrystals, 3 ml oleylamine can be injected into the flask at 150° C. to initiate nucleation and the nanocrystals can be allowed to grow for 4 minutes before quenching the contents of the flask by immersing the flask in water. For the preparation of 2.5 nanometer nanocrystals, a mixture of 1.5 ml oleylamine and 1.5 ml octadecene can be injected into the flask at 150° C. It should be understood that the quantities of reactants can be adjusted to produce the desired amount of nanocrystals.

To avoid premature decomposition of Sn(dedc)₄ for preparations carried out above 150° C., Sn(dedc)₄ can be dissolved in oleylamine and octadecene and injected into the flask with oleylamine, rather than dissolving and heating it to the reaction temperature with the other complexes. For example, for the preparation of 5 nanometer nanocrystals, Sn(dedc)₄ can be dissolved in a mixture of 1.5 ml oleylamine and 1.5 ml octadecene and injected into the flask at 175° C. For the preparation of 7 nanometer nanocrystals, Sn(dedc)₄ can be dissolved in a mixture of 0.75 ml oleylamine and 2.25 ml octadecene and injected into the flask at 175° C. All the other steps of the preparation and purification can, if desired, remain the same.

Nanocrystals can be precipitated from the dispersion using, for example, ethanol, and centrifuging for 5 minutes at 4000 revolutions per minute (rpm). The supernatant can be discarded and the nanocrystals can be redispersed in toluene. The precipitation and dispersion steps can optionally be repeated multiple times to wash out excess reactants. Finally, if desired, the nanocrystals can be dispersed in toluene and kept for further use.

In certain embodiments, the nanocrystals have an average particle size of 1 nanometer to 100 nanometers. In preferred embodiments, the nanocrystals have an average particle size of less than 2 nanometers to tens of nanometers.

The nanocrystals disclosed herein can be dispersed in various solvents (e.g., organic solvents or water) to form nanocrystal inks. Typically, the nanocrystals prepared as described herein can be readily dispersed in an organic solvent such as toluene to form a nanocrystal organic ink.

Alternatively, water based CZTS inks can be also prepared. Water based CZTS inks can be advantageous, for example, by avoiding the use of organic solvents. To make aqueous dispersions of CZTS nanocrystals, the organic ligands that stabilize CZTS nanocrystals in organic solvents can be stripped and exchanged by S²⁻ ions. These ions surround the CZTS nanocrystals and can electrostatically stabilize the nanocrystals in aqueous solutions. In a typical ligand exchange procedure, the CZTS nanocrystals capped with oleylamine and dispersed in toluene in concentrations of 2 mg/mL can be contacted with a K₂S solution in water and formamide. For 3 ml of 2 mg/mL CZTS nanocrystal dispersion 100 μL of 9-10 M K₂S solution in water can be mixed with 1 mL of formamide and added to the CZTS nanocrystal dispersion in toluene. The organic toluene dispersion and aqueous K₂S solution phase into separate layers. The two-phase mixture can be stirred, for example, at 1200 rpm for 90 minutes, resulting in the transfer of the CZTS nanocrystals capped with S²⁻ ions from toluene to the aqueous phase. The toluene supernatant can be removed, for example, after centrifugation for 3 to 5 minutes at 4000 rpm. The CZTS nanocrystals can then be precipitated by addition of 1 mL of ethanol, centrifuged, washed, and redispersed in deionized water, for example, by sonication.

Nanocrystal inks can conveniently be coated on a substrate and heated to form a film of the metal chalcogenide. For example, thin films of CZTS, CZTSe and CZTSSe can be formed by coating surfaces of suitable substrates with nanocrystals and annealing the resulting nanocrystal film to form polycrystalline films. The surfaces can be coated from colloidal dispersions of nanocrystals (i.e., inks) using a variety of methods including, but not limited to, drop casting, spin coating, and/or dip coating.

CZTS nanocrystals (e.g., crystals with a diameter of 1 to 20 nm) can melt at temperatures much lower than bulk CZTS. Consequently, rapid grain growth at low temperatures is possible. Thus, CZTS nanocrystals can be coated onto a surface of a substrate and annealed using rapid thermal annealing at temperatures of 300 to 700° C. to provide a CZTS film. In rapid thermal annealing the temperature of the substrate and the film can be raised rapidly to the desired temperature (e.g., 300 to 700° C.) at rates of, for example, 1 to 5 degrees per second, then held at that temperature for a desired period of time for grain growth and recrystallization. This period of time may range from 0 to 1 hour, and typically are 5 to 15 minutes. The substrate and film are then cooled to room temperature, preferably at a rate slow enough to avoid film peeling or cracking due to thermal contraction, particularly if the substrate and the film have a high thermal expansion coefficient mismatch. Typical cooling rates may be 10° C. per minute. Annealing can be conducted in vacuum, under inert atmosphere such as nitrogen or argon, or even in a sulfidizing environment with H₂S and sulfur vapor to replenish any sulfur that may escape the film during annealing. Brief rapid thermal annealing for 5 to 15 minutes as described herein typically does not reduce sulfur in the film. However, if films are annealed for times exceeding 1 hour, sulfur content in the films may decrease, and films may even become metallic. Conditions effective to achieve a particular balance between rapid crystallization and excessive sulfur loss can depend on a variety of factors, including, for example, the equipment being used. However, heating rates and annealing times can generally be adjusted to obtain CZTS films without significant sulfur loss. Thus, rapid thermal annealing can provide a method for obtaining large grained CZTS films, which can be advantageous, for example, in high throughput production.

Alternatively, thin films of metal chalcogenides can be formed on surfaces of suitable substrates directly from the metal complexes without forming the nanocrystal inks. For example, in some embodiments, the copper, zinc, and/or tin compounds selected from the group consisting of chalcogenocarbamates, dichalcogenocarbamates, mercaptides, thiolates, dithiolates, thiocarbonates, dithiocarbonates, trithiocarbonates, and combinations thereof (e.g., copper, zinc, and/or tin dichalcogenocarbamates) can be heated to a melt in the absence of a solvent (e.g., at a temperature of 150° C. to 900° C.), thus forming the metal chalcogenide. For one example, a mixture of suitable copper, zinc, and/or tin compounds (e.g., copper, zinc, and/or tin dichalcogenocarbamates) can be dissolved, dispersed, or suspended in a suitable solvent, the solvent mixture can be coated on a substrate, the solvent removed followed by heating to form a film of the metal chalcogenide. For certain embodiments, the dichalcocarbamates can optionally be heated in the presence of an amine (e.g., oleylamine).

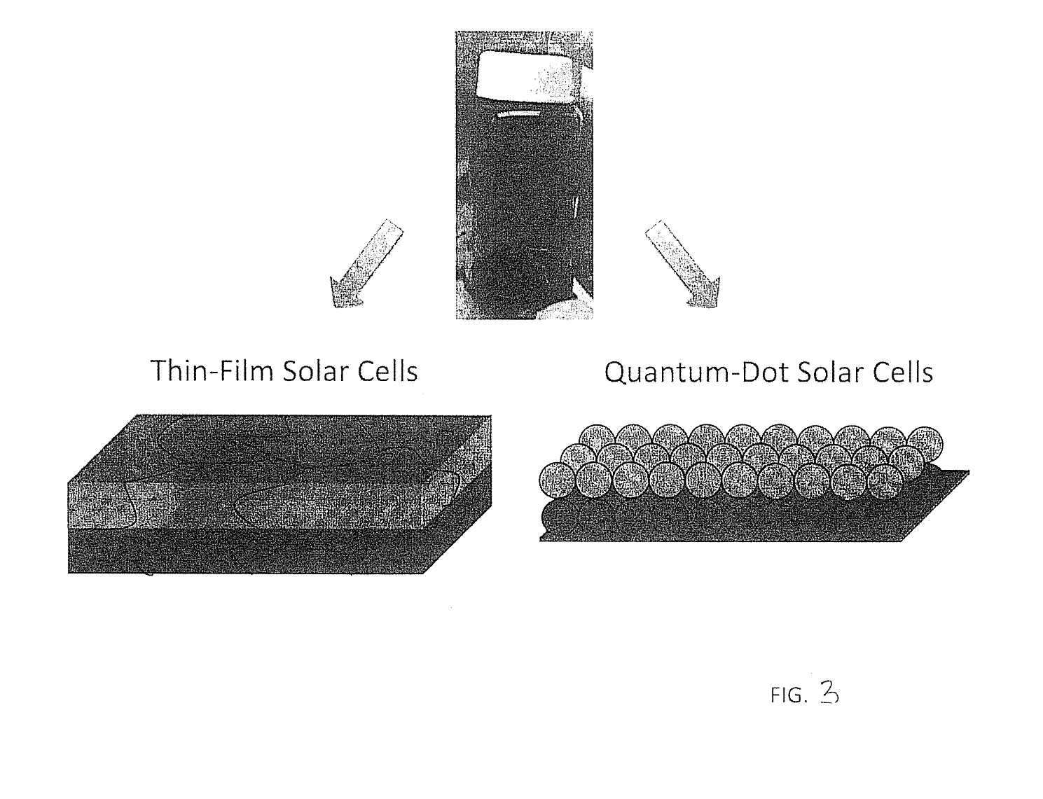

FIG. 3 shows two ways in which the nanocrystals can be used in the assembly of two different types of thin-film solar cells. Either one of the methods may be preferred depending on, among other things, the rest of the solar cell manufacturing process and the choice of substrate. In the first type, nanocrystals whose sizes are less than the exciton Bohr radius (QDs) can be cast on a desired surface to form a QD film. Following, the long alkyl chain ligands can be exchanged with shorter ligands such as pyridine or ethane dithiol to bring the nanocrystals closer for better electronic coupling and charge transport. The ligands can be exchanged by dipping the film in a solution of the shorter ligand. In this way, films for quantum-dot solar cells such as those described by Luther et al. or Leschkies et al. can be formed. See, for example, Luther et al., Nano Letters 8, 3488 (2008); and Leschkies et al., ACS Nano 11, 3638 (2009). Multiple coatings can be formed layer-by-layer to get thicker films and to fill the cracks that form in the film after exchanging the long ligands with shorter ones.

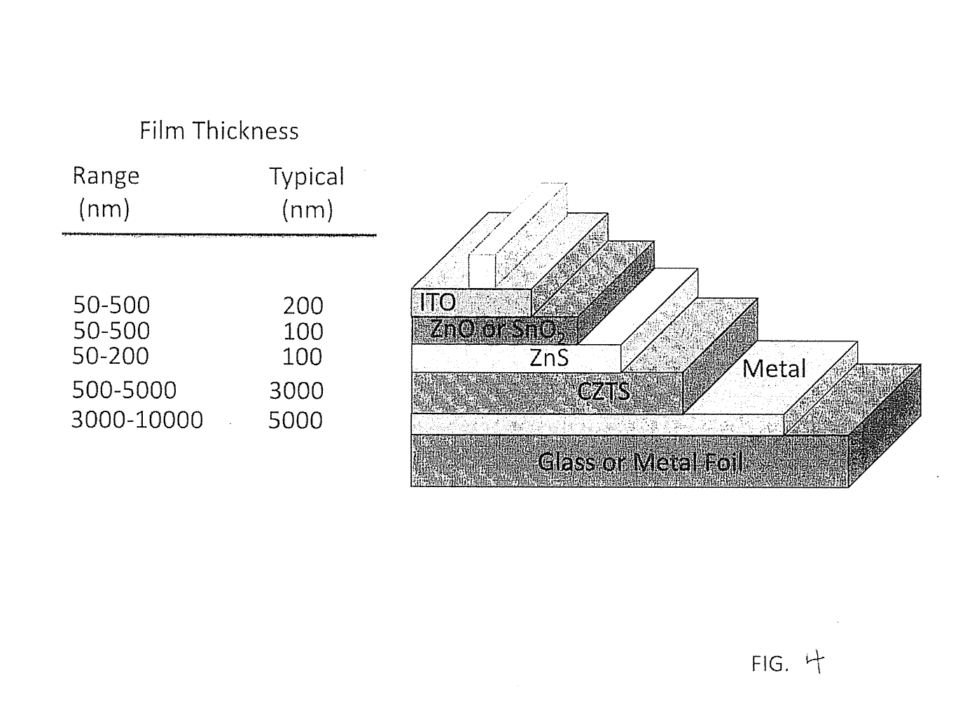

Alternatively, the nanocrystal film can be annealed after ligand exchange to form a thin CZTS film (FIG. 3) for a thin-film solar cell such as that shown in FIG. 4. In this case a volatile short chain labile ligand such as pyridine can be preferred, because it can be removed by desorption under vacuum and heating, without substantial decomposition. For example, thin films of CZTS have been formed by (1) casting thin nanoparticle films, (2) exchanging oleic acid and oleylamine ligands with pyridine, (3) desorbing pyridine under vacuum, and (4) annealing the nanocrystal film in vacuum or under inert (e.g., argon or nitrogen) atmosphere.

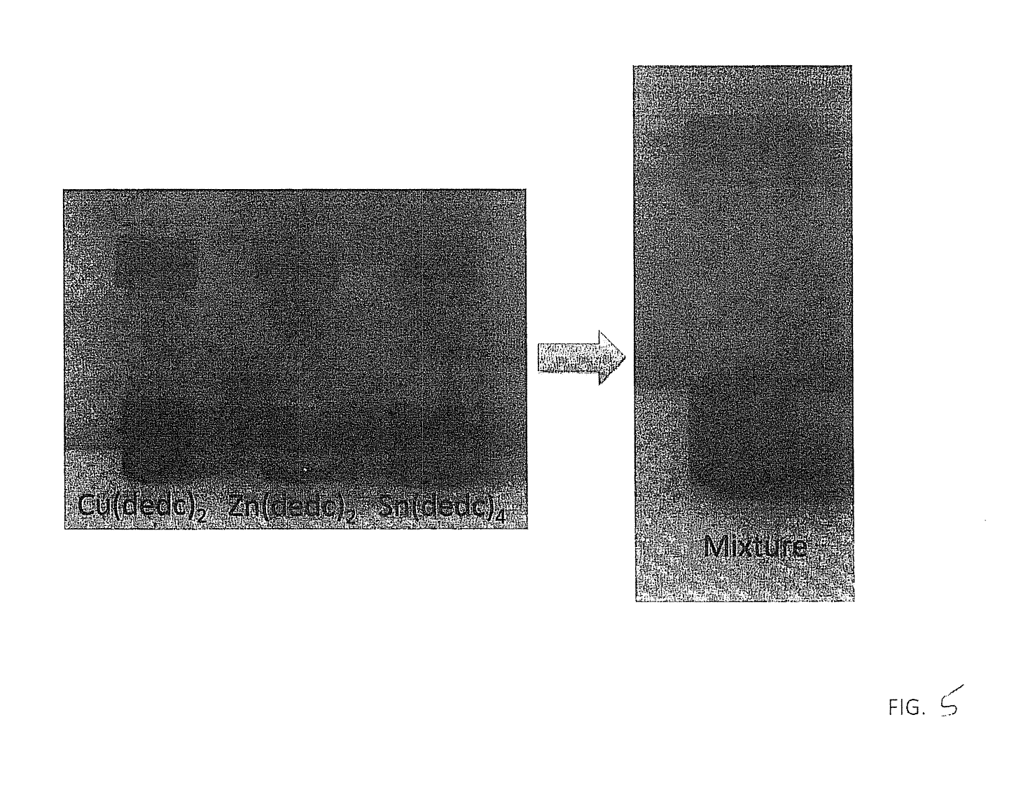

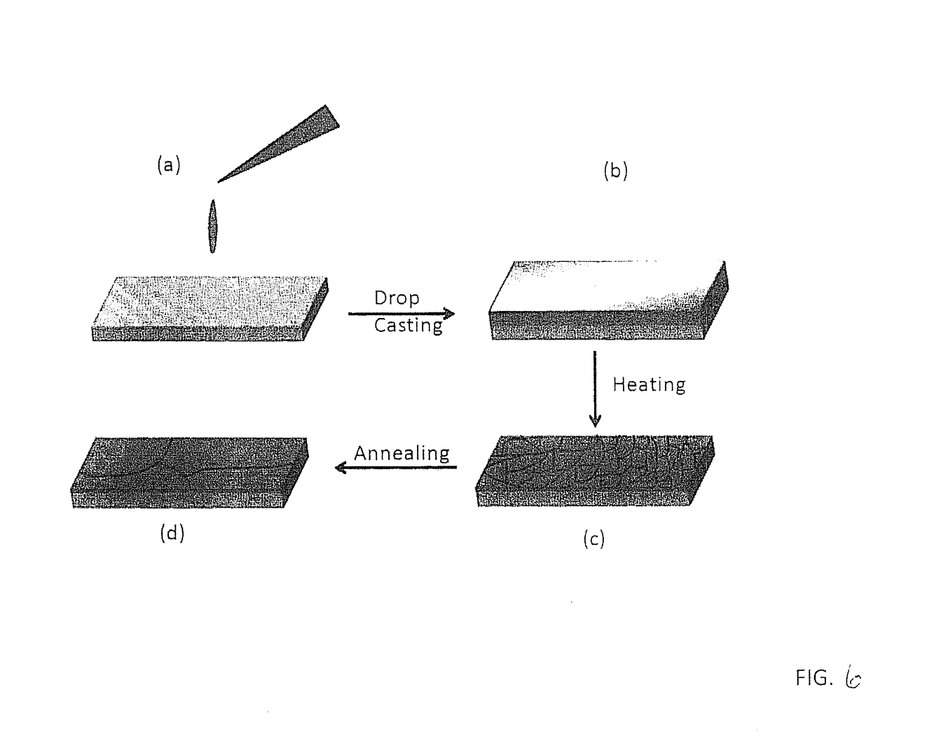

For certain embodiments, the molten mixtures of the copper, zinc, and tin dithiocarbamates can be spread over desired substrates and subsequently decomposed to form CZTS films. Moreover, changing the groups attached to the carbamates can alter the melting temperature of the various complexes. However, there are some groups for which the complexes do not melt before decomposing, instead decomposing in their solid form to give the corresponding sulfide. CZTS films can be formed by dissolving the metal dithiocarbamate complexes in a solvent such as chloroform, placing a known amount of this solution on the substrate surface and heating the substrate. As the substrate is heated to temperatures above the boiling point of the solvent, the solvent evaporates, leaving behind a mixed powder of the metal complexes behind. As heating is continued, this mixture can subsequently melt to form a liquid mixture of the complexes. Further heating to higher temperatures can form solid CZTS. The presence of an amine additive (for example oleylamine, dodecylamine, etc.) in the solvent can decrease the decomposition temperature of these metal complexes and in some cases cause the complex to decompose even before the mixture reaches the melting temperature. A preferred method for making films from these complexes is to first dissolve stoichiometric or any desired amounts of the metal dithiocarbamate complexes in an organic solvent (e.g., chloroform, acetone, etc.) to form individual solutions (see FIG. 5) of the complexes, and then use a mixture of these solutions (see FIG. 5) to form a thin liquid film using available and known methods. These methods may include slot coating, drop casting, or dip coating on various substrates, which may include silicon, metal coated soda lime glass, quartz, glass, metal foils, etc. Other solvents or mixtures of solvents may also be used to adjust the viscosity and volatility of the solvent. The substrate can then be heated in vacuum, air, inert atmosphere, sulfidizing atmosphere or selenizing atmosphere at different ramp rates to temperatures ranging from 150° C. to 900° C. to give CZTS. The material can be further annealed at these elevated temperatures to cause grain growth and improve the solar cell performance. FIG. 6 illustrates a schematic representation of the sequence of steps for deposition of metal sulfide films from a solution of metal complexes.

One approach is to spray a solution of these complexes on a heated substrate with temperatures ranging from 200° C. to 800° C. The metal complexes decompose into the corresponding sulfide as soon as they come in contact with the substrate. Another approach is to aerosolize the precursor solution containing the metal dithiocarbamates and place the heated substrate to be coated in the path of the aeresol particles which, upon impinging on the heated substrate, can decompose to form the film. Another approach is to aerosolize the precursor solution containing the metal dithiocarbamates, and heat the aeresol particles in flight to form CZTS particles. Placing a heated substrate in the path of these particles can form the film by impaction. Diselenocarbamate complexes can also be used in a similar manner as the dithiocarbamates to give metal selenides instead of sulfides. A mixture of these two types of complexes gives a final absorber layer containing both sulfur and selenium, for example, in the ratio of the initial precursor mix. This approach of making absorber layer directly from the metal complexes can avoid the intermediate step of forming the nanocrystal colloidal dispersion.

Finally, the solar cell architectures that can be realized using the CZTS film deposition methods described herein need not be limited to that in FIG. 4. Solar cells based on junctions between p-type CZTS and n-type CZTS can also be made using the methods above. For example, increasing the amount of copper as compared to zinc and vice versa, the final absorber layer can be made either p-doped or n-doped respectively. These p and n doped layers can form a p-n homojunction of CZTS, CZTSe and CZTSSe. Moreover, one can also make tandem cells where CZTS absorbers with different bandgaps are used to make solar cells that are stacked on top of each other and connected in series to absorb different parts of the solar spectrum to increase power conversion efficiency.

One of skill in the art, particularly in view of the teachings of the present disclosure, can select desired ratios of copper, zinc, and/or tin dichalcocarbamates to provide metal chalcogenides of the formula Cu_{2+x+z}Zn₁₋ₓSn_{1-z}A₄, wherein A represents one or more chalcogens; −1≦x≦1; −1≦z≦1; and with the proviso that when x=z they are not equal to 1.

Changing relative amounts of the metal complexes in the reacting solution can change the composition of the nanocrystals. For example, copper tin sulfide (Cu₃SnS₄) can be prepared by replacing all Zn(dedc)₂ with Cu(dedc)₂. Using the methods described herein and only changing the proportions of the metal complexes in the reacting solution, nanocrystals of the formula Cu_{2+x+z}Zn₁₋ₓSn_{1-z}S_{y}Se_{4-y} can be prepared, wherein −1≦x≦1, 0≦y≦4, and −1≦z≦1. For example, it may be desired to make copper deficient or copper rich CZTS (e.g., Cu_{2+w}Zn_{1-w}SnS_{y}Se_{4-y}, wherein w is a small positive or negative number) to alter the carrier type or electronic doping in CZTS nanocrystals. Hereinafter we refer to all these films (CZTS, CZTSe, and CZTSSe) with differing Cu, Zn, Sn, S, and Se stoichiometry as CZTS for brevity. It is understood that the composition can be adjusted by using appropriate desired combinations and amounts of the corresponding metal thiocarbamates or the corresponding selenocarbamates.

Useful metal chalcogenides that can be prepared by the methods disclosed herein include, but are not limited to, those of the formulas Cu_{2+z}ZnSn_{1-z}S_{y}Se_{4-y}; Cu₂ZnSnS_{y}Se_{4-y}; Cu₃ZnS_{y}Se_{4-y}; CuZnSn₂S_{y}Se_{4-y}; Cu_{1+z}Zn₂Sn_{1-z}S_{y}Se_{4-y}; CuZn₂SnS_{y}Se_{4-y}; Cu₂Zn₂S_{y}Se_{4-y}; Zn₂Sn₂S_{y}Se_{4-y}; Cu_{3+z}Sn_{1-z}S_{y}Se_{4-y}; Cu₃SnS_{y}Se_{4-y}; Cu₂Sn₂S_{y}Se_{4-y}; Cu₂₊ₓZn₁₋ₓSnS_{y}Se_{4-y}; Cu₃₊ₓZn₁₋ₓS_{y}Se_{4-y}; and Cu₁₊ₓZn₁₋ₓSn₂S_{y}Se_{4-y}, wherein 0≦y≦4. Particularly useful metal chalcogenides include those of the formula Cu₂ZnSnS_{y}Se_{4-y}, wherein 0≦y≦4.

Other particularly useful metal chalcogenides include copper-rich copper zinc tin chalcogenides of the formula Cu₂₊ₓZn₁₋ₓSn S_{y}Se_{4-y}, wherein: 0≦y≦4; and 0<x<1. Such copper-rich copper zinc tin chalcogenides can be useful for preparing p-doped metal chalcogenide layers.

Other particularly useful metal chalcogenides include copper-deficient copper zinc tin chalcogenides of the formula Cu₂₊ₓZn₁₋ₓSn S_{y}Se_{4-y}, wherein: 0≦y≦4; and −1<x<0. Such copper-deficient copper zinc tin chalcogenides can be useful for preparing n-doped metal chalcogenide layers.

Metal chalocogenides as disclosed herein can be used, for example, to prepare solar cells. Disclosed herein are solar cells, and methods of making solar cells, that include a substrate and one or more copper zinc tin chalcogenide layers.

In certain embodiments the copper zinc tin chalcogenide is copper-deficient and is of the formula Cu₂₊ₓZn₁₋ₓSn S_{y}Se_{4-y}, wherein: 0≦y≦4; and −1<x<0. In other certain embodiments, the copper zinc tin chalcogenide is copper-rich and is of the formula Cu₂₊ₓZn₁₋ₓSn S_{y}Se_{4-y}, wherein: 0≦y≦4; and 0<x<1. In some embodiments the solar cells include one or more copper-deficient copper zinc tin chalcogenide layers and one or more copper-rich copper zinc tin chalcogenide layers. Optionally, the solar cells can further include a zinc sulfide, a tin oxide, and/or a zinc oxide buffer layer over at least one metal chalcogenide layer or layers.

The band gap of the CZTS nanocrystals determines the wavelengths of light that the nanocrystals absorb. CZTS has a bandgap of approximately 1.5 eV, ideal for making solar cells. Moreover, this bandgap makes the theoretical maximum efficiency of CZTS based solar cells nearly the same as that for CIGS and CdTe based solar cells.

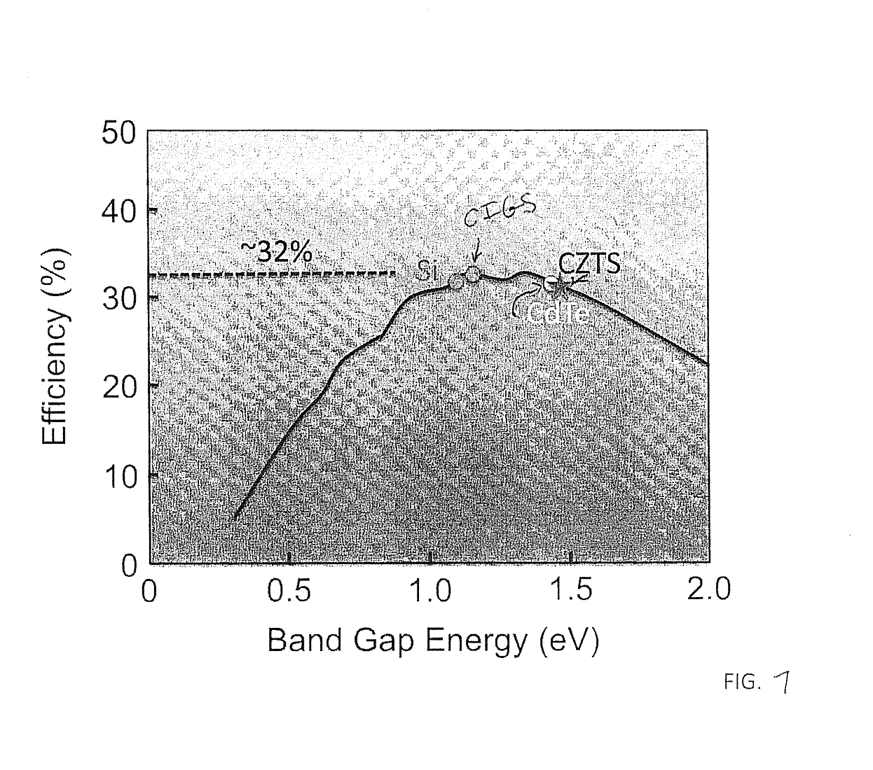

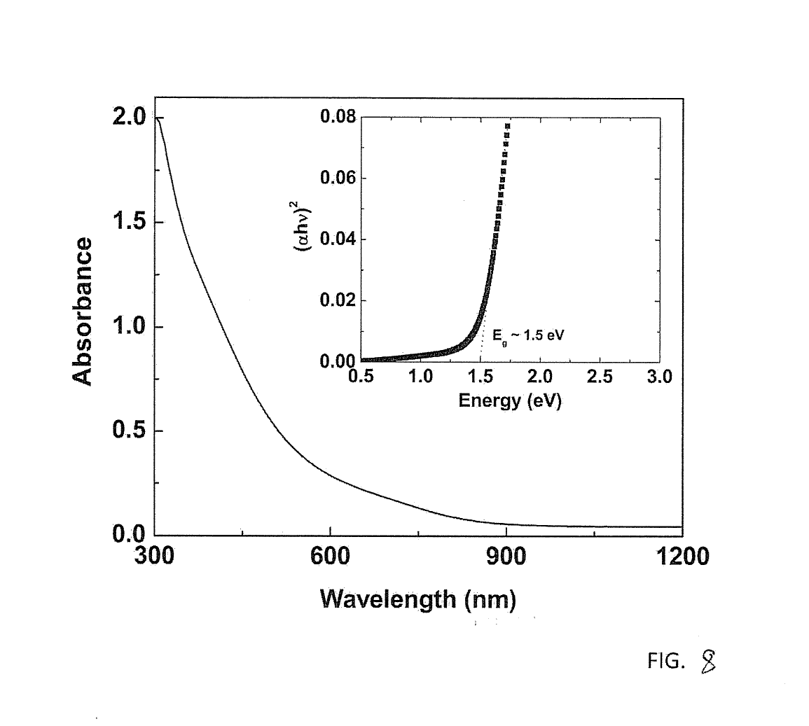

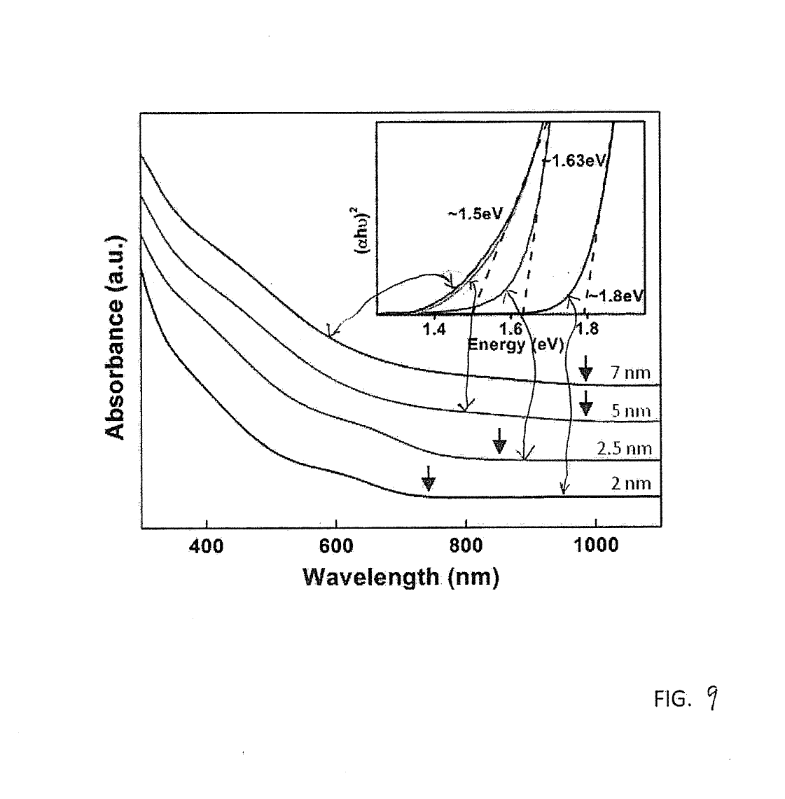

FIG. 7 shows the theoretical maximum efficiency for CIGS, Silicon, CdTe, and CZTS solar cells. FIG. 8 shows the optical absorption spectrum of larger than approximately 10 nanometer diameter CZTS nanocrystals prepared using Cu(dedc)₂, Zn(undc)₂, and Sn(dmdc)₂. Tauc plot analysis shown in the inset gives a band gap of 1.5 eV. FIG. 9 shows the optical absorption spectra from different size CZTS nanocrystals made with Cu(dedc)₂, Zn(dedc)₂, and Sn(dedc)₂. While, the 7 nanometer diameter nanocrystals give a band gap of 1.5 eV, the edge of the optical absorption spectrum and other features such as the broad peak after the onset of the absorption are blue shifted as the nanocrystal diameter decreases from 7 nanometers to 2 nanometers. While this shift is nearly undetectable between the absorption for 7 nanometer and 5 nanometer diameter nanocrystals, it becomes significant when the average diameter is reduced to 2.5 nanometers and then further to 2 nanometers. This shift is due to quantum confinement in nanocrystals whose diameter is less than the exciton Bohr radius. Such nanocrystals are referred to as quantum dots (QDs) and they can be used to make quantum dot solar cells as well as thin film solar cells. See, for example, Nozik, Physica E 14, 115 (2002); Luther et al., Nano Letters 8, 3488 (2008); and Leschkies et al., ACS Nano 11, 3638 (2009).

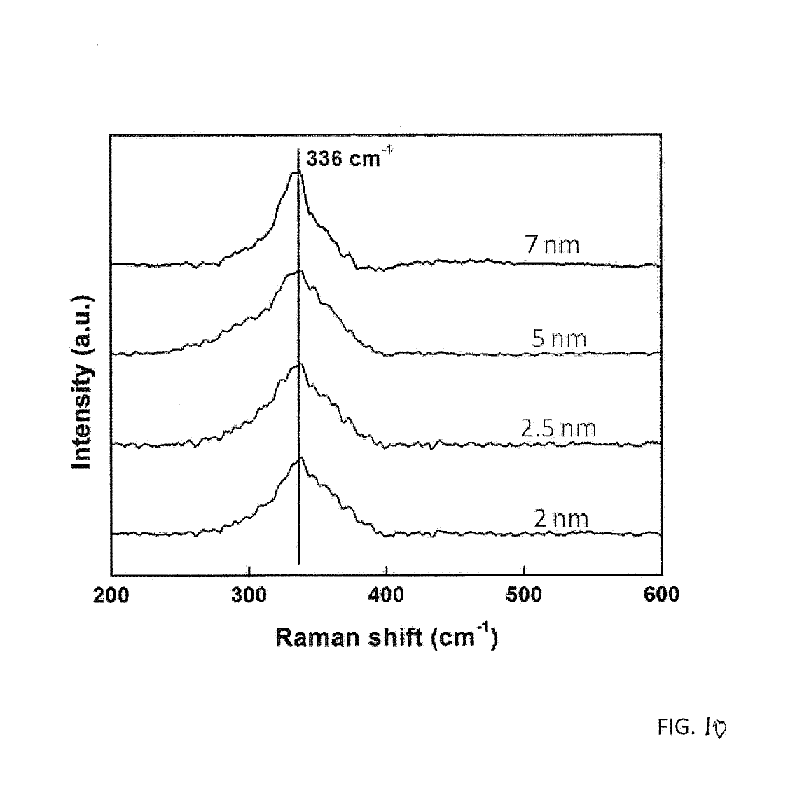

Raman scattering from CZTS is unambiguous and can be used in addition to the above characterization methods to determine the phase purity of the nanocrystals. FIG. 10 shows the Raman scattering from different size nanocrystals. Only a single Raman peak at 336 cm⁻¹ was detected and the location of this peak matched that expected from bulk CZTS. However, Raman scattering peaks observed from these nanocrystals were very broad as compared to bulk CZTS. Broadening of Raman peaks has been attributed to phonon confinement within the nanocrystals and has been observed previously for nanocrystals of other materials. Raman peaks for Cu₂S, ZnS, and SnS₂ are expected at 472 cm⁻¹, 351 cm⁻¹, and 315 cm⁻¹, respectively. The widening of the CZTS peak due to small crystal size may mask the presence of ZnS and SnS₂. However, SnS₂ is typically not detected by XRD. Moreover, annealing of films cast from these nanoparticles results in a sharp Raman peak at 336 cm⁻¹, with no detectable Raman scattering from ZnS and SnS₂. Thus, within the detection limit of Raman scattering, sulfides other than CZTS are typically not observed.

The present invention is illustrated by the following examples. It is to be understood that the particular examples, materials, amounts, and procedures are to be interpreted broadly in accordance with the scope and spirit of the invention as set forth herein.

### EXAMPLES

### Example 1

To prepare Cu(dedc)₂, sodium diethyldithiocarbamate (9.0 g) in ethanol was added dropwise to 85 mg/ml copper chloride (4.23 g) solution in ethanol while constantly stirring. The black precipitate that formed upon reaction was filtered and washed multiple times with water before drying in a desiccator. Cu(dedc)₂ crystals were purified by recrystallization from chloroform and dried overnight in vacuum before use. These crystals melted at 200° C.

To prepare Zn(dedc)₂, sodium diethyldithiocarbamate (9.0 g) in ethanol was added dropwise to 68 mg/ml zinc chloride (3.38 g) solution in ethanol while constantly stirring. The white precipitate that formed upon reaction was filtered and washed multiple times with water before drying in a desiccator. Zn(dedc)₂ crystals were purified by recrystallization from chloroform and dried overnight in vacuum before use. These crystals melted at 181° C.

To prepare Sn(dedc)₄, sodium diethyldithiocarbamate (12.85 g) in ethanol (200 ml) was added dropwise to 50 mg/ml tin tetrachloride (2.5 g) solution in ethanol (50 ml) while constantly stirring. The orange precipitate that formed upon reaction was filtered and washed multiple times with water before drying in a desiccator. Sn(dedc)₄ crystals were purified by recrystallization from acetone and dried overnight in vacuum before use. These crystals melted at 169° C.

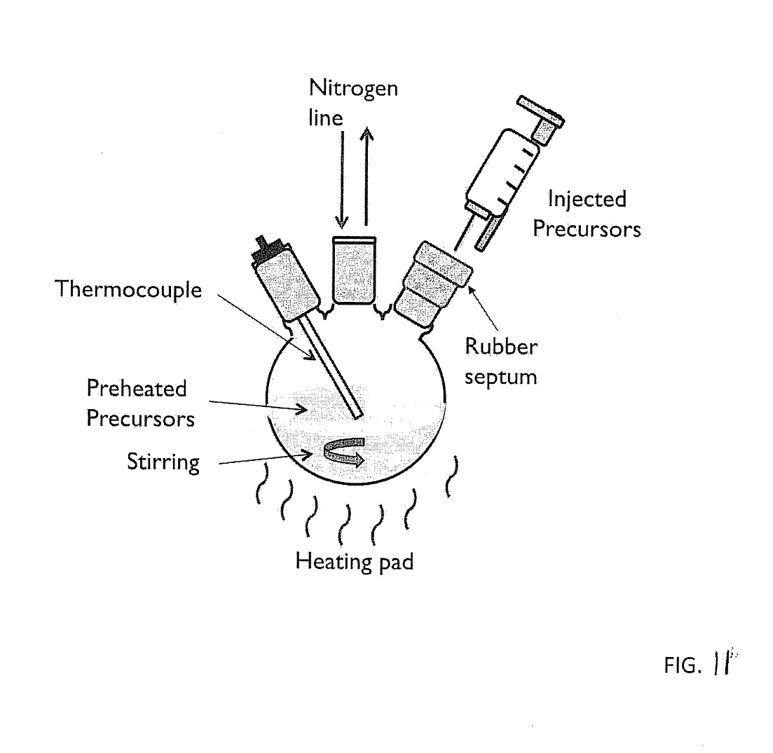

CZTS nanocrystals were prepared in a nitrogen atmosphere using a Schlenk line apparatus. In a typical preparation, 18 ml octadecene and 2 ml oleic acid were mixed in a 100 ml three neck flask (FIG. 11) and 27 mg Cu(dedc)₂, 13.6 mg Zn(dedc)₂, and 26.7 mg Sn(dedc)₄ were added to this mixture. Following, the flask containing the metal dithiocarbamates was connected to the Schlenk line and the contents of the flask were degassed multiple times at 60° C.

The amount of oleylamine injected to decompose these complexes influences the available nucleation sites for growth of the nanocrystals. By varying the amount of oleylamine injected and the growth temperature, the average diameter of the nanocrystals can be tuned.

In a typical preparation, the contents of the flask were heated to the desired temperature and a specific volume of oleylamine was injected into this mixture. The nanocrystal size was tuned by changing the temperature at which olelyamine was injected and the amount of oleylamine. For example, to prepare 2 nanometer diameter nanocrystals, 3 ml oleylamine was injected into the flask at 150° C. to initiate nucleation and the nanocrystals were allowed to grow for 4 minutes before quenching the contents of the flask by immersing the flask in water. For the preparation of 2.5 nanometer nanocrystals, a mixture of 1.5 ml oleylamine and 1.5 ml octadecene were injected into the flask at 150° C.

To avoid premature decomposition of Sn(dedc)₄ for preparations carried out above 150° C., Sn(dedc)₄ was dissolved in oleylamine and octadecene and injected into the flask with oleylamine rather than dissolving and heating it to the reaction temperature with the other complexes. For example, for the preparation of 5 nanometer nanocrystals, Sn(dedc)₄ was dissolved in a mixture of 1.5 ml oleylamine and 1.5 ml octadecene and injected into the flask at 175° C. For the preparation of 7 nanometer nanocrystals, Sn(dedc)₄ was dissolved in a mixture of 0.75 ml oleylamine and 2.25 ml octadecene and injected into the flask at 175° C. All the other steps of the preparation and purification remained the same.

The nanocrystals were precipitated from the dispersion using ethanol and were centrifuged for 5 minutes at 4000 revolutions per minute (rpm). The supernatant was discarded and the nanocrystals were redispersed in toluene. The precipitation and dispersion steps were repeated multiple times to wash out the excess reactants. Finally the nanocrystals were dispersed in toluene to prepare a nanocrystal organic ink that was kept for further use. Alternatively, water based inks could also be prepared as described herein above.

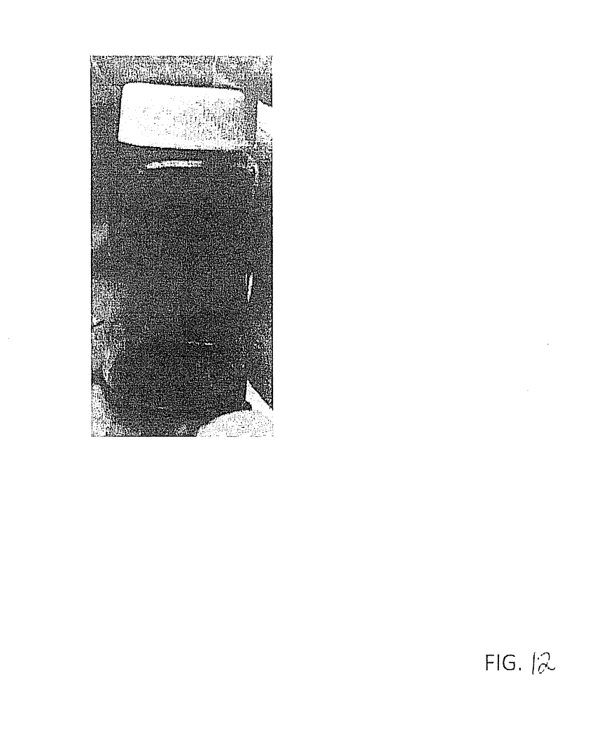

FIG. 12 shows a digital photograph of a colloidal CZTS nanocrystal dispersion or ink formed using the method described above. In this form, the nanocrystals were dispersed in the organic solvent and their surfaces were covered with a monolayer of a mixture of oleic acid and oleylamine. The nanocrystals were easily dispersed in organic solvents because they were covered with these long alkyl chain ligands. It is possible to exchange the oleic acid and oleylamine with shorter hydrophilic chains to form nanocrystal dispersions in water or other protic solvents.

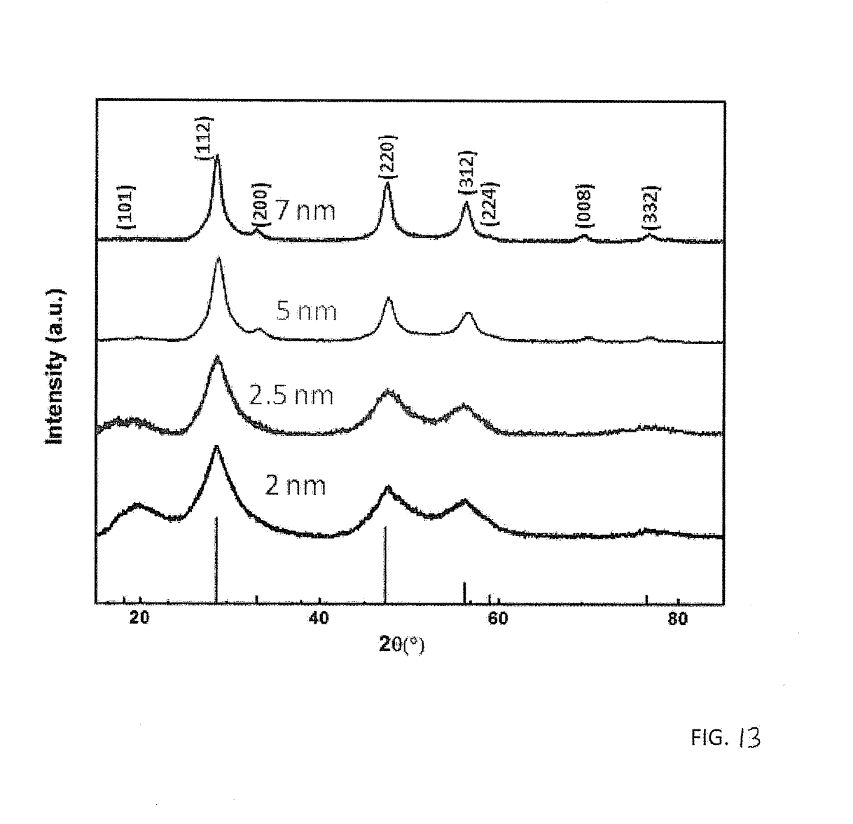

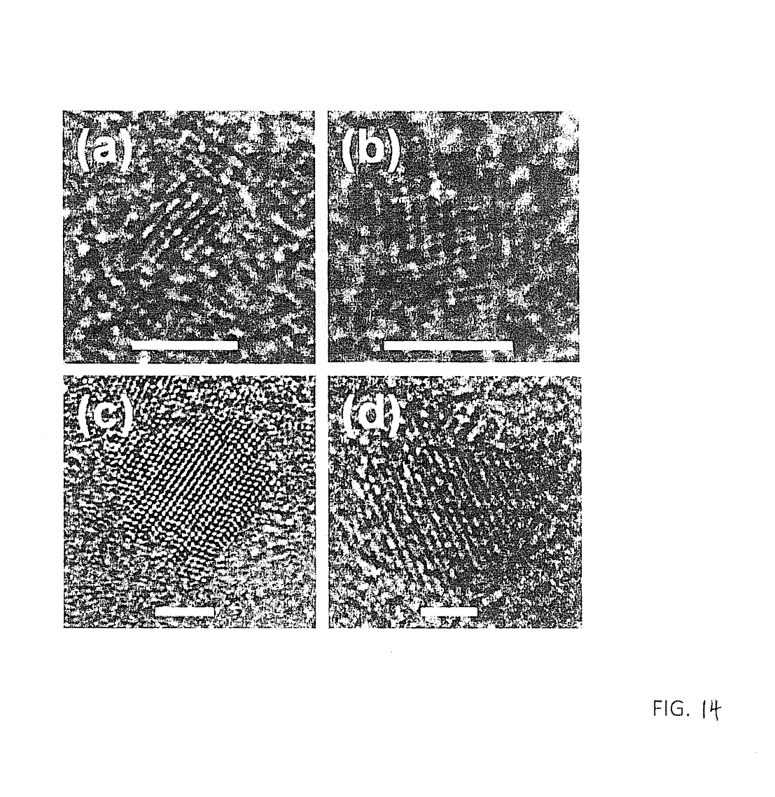

FIG. 13 shows the X-ray diffraction (XRD) patterns from CZTS nanocrystals whose sizes were tuned by varying the preparation temperature and the oleylamine concentration as described above. The XRD from the nanocrystals matches that for CZTS (JCPDS card no 26-0575). The crystallite sizes extracted from the width of the (112) diffraction peak at 28.5° using the Debye-Scherrer equation range from 2 nanometers to 7 nanometers and are in agreement with the high resolution transmission electron micrographs (HRTEM) of individual crystals (FIG. 14) obtained from the corresponding ensemble of nanoparticles. FIG. 14 shows the HRTEM images of different size nanoparticles, which confirm that individual particles were crystalline. The spacing between the lattice planes were consistent with those expected for CZTS. The final nanocrystal size increased with increasing oleylamine amount injected into the solution and with decreasing growth temperature. In addition to the CZTS peaks, the XRD shows a broad diffraction at 2θ of approximately 20°. This broad feature is due to scattering from the organic ligands and its intensity is larger for small nanocrystals because the organic ligands occupy a larger fraction of the total nanoparticle volume in these nanocrystals than in the large ones.

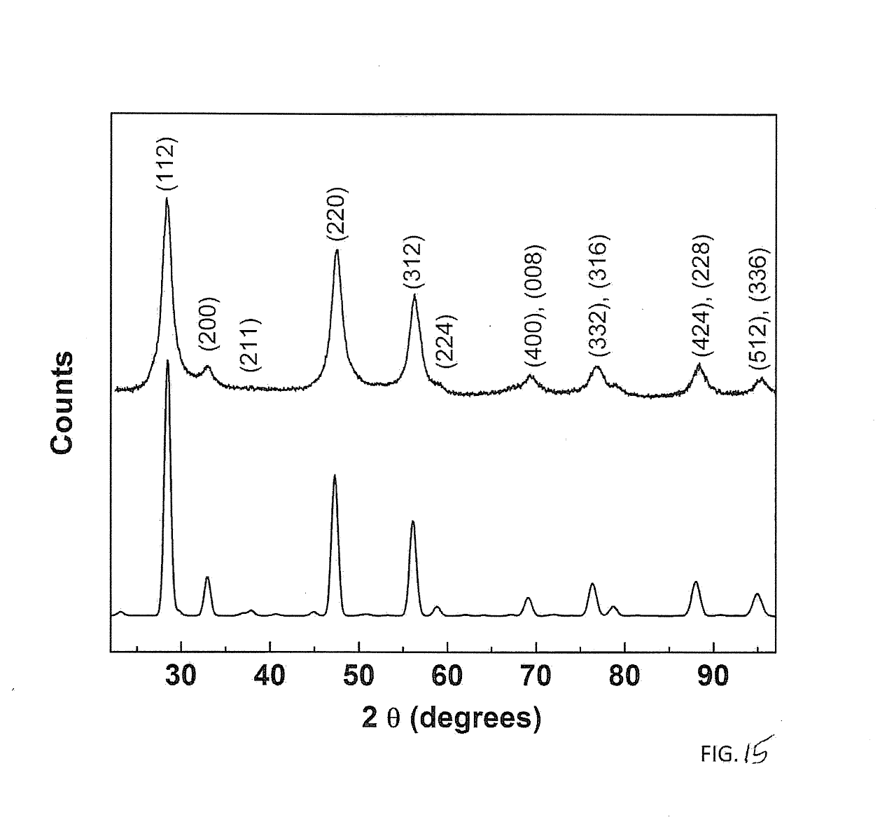

As the nanocrystals get larger, the peaks become better defined, sharper, and more intense. As an example, FIG. 15 shows XRD for 10 nanometer diameter nanocrystals that were prepared using copper diethyldithiocarbamate {Cu(S₂CN(C₂H₅)₂)₂; Cu(dedc)₂}, zinc undecyldithiocarbamate {Zn(S₂CNH(C₁₁H₂₃))₂; often abbreviated as Zn(undc)₂} and tin dimethyldithiocarbamate {Sn(S₂CN(CH₃)₂)₄; often abbreviated as Sn(dmdc)₂}. This example illustrates that other complexes can be used to prepare similar compounds. FIG. 15 also shows that the measured XRD matches closely to the calculated XRD expected from 10 nanometer CZTS nanocrystals both in location and in relative intensities.

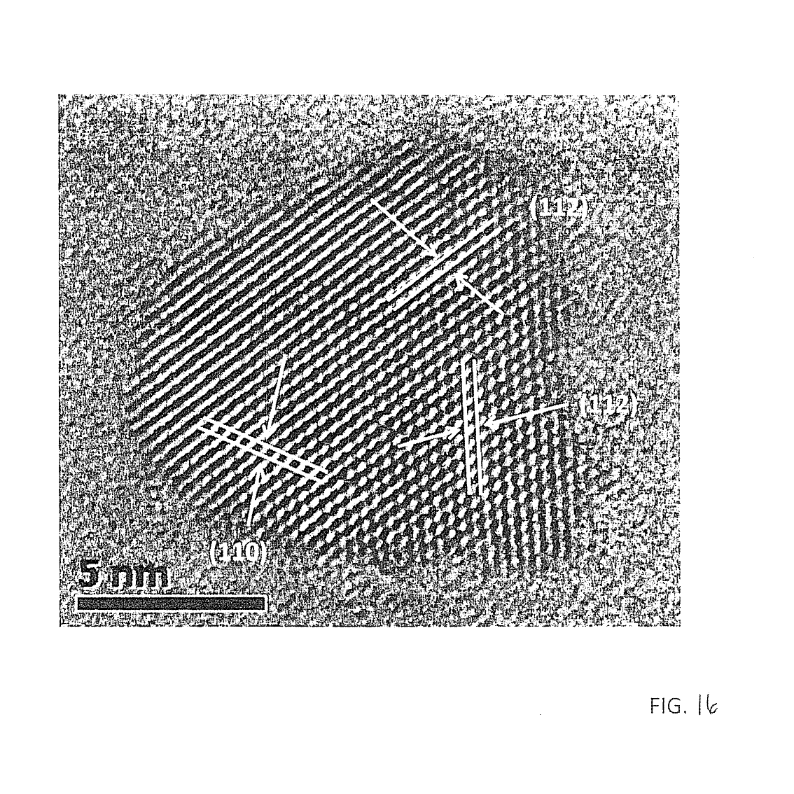

FIG. 16 shows the HRTEM for larger, approximately 10 nanometer CZTS nanocrystals as well as the various atomic planes whose spacing match those expected for CZTS.

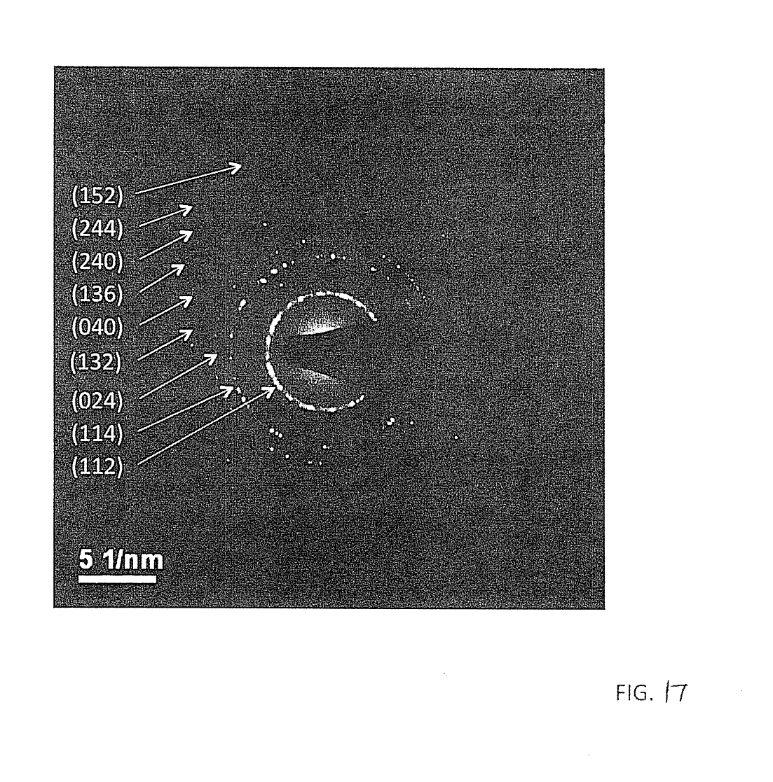

FIG. 17 is selected area electron diffraction from an ensemble of such crystals shown in FIG. 16. The diffraction rings are consistent with CZTS atomic planar spacings and could be indexed to diffraction from CZTS planes, consistent with the XRD data.

Moreover, the compositions of various batches of nanocrystals were determined using inductively coupled plasma-mass spectroscopy (ICP-MS) as well as electron probe microanalysis (EPMA) and were consistent with the stoichiometry of Cu₂ZnSnS₄. Table 1 shows a typical result.

TABLE 1
Analytical Data for Cu₂ZnSnS₄

| | Number of Atoms | Number of Atoms |
|---|---|---|
| Element | (Theoretical) | Measured by EPMA |
| Cu | 2 | 1.95 ± 0.03 |
| Zn | 1 | 1.01 ± 0.03 |
| Sn | 1 | 1.01 ± 0.02 |
| S | 4 | 4.02 ± 0.04 |

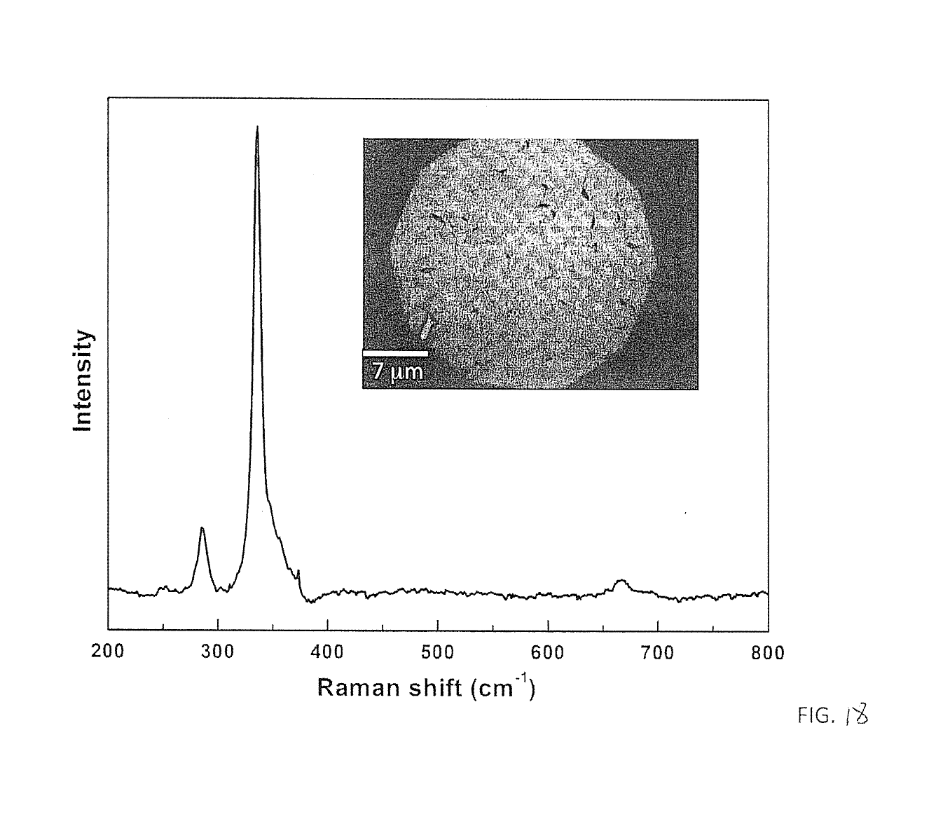

The XRD and Raman scattering from these films show that the films are CZTS. In fact, upon annealing, the XRD and Raman peaks of CZTS become sharper and more intense than before annealing, indicating that grain growth takes place. For example, FIG. 18 shows the Raman scattering and an optical image of the CZTS film formed in this way.

### Example 2

An alternative method for making CZTS films from the metal dithiocarbamate complexes avoids forming nanocrystals and offers the means to form the film by applying the complexes directly onto the surface of the substrate. Metal dithiocarbamate complexes have the useful property that they melt before they decompose. For example, FIG. 1 shows the DSC data for copper, zinc, and tin diethyldithiocarbamates. The sharp endothermic peaks in FIG. 1 between 160° C. and 200° C. correspond to the melting of the complexes.

The formation of thin films of metal sulfides from the dithiocarbamate complexes was studied using an X-ray diffractometer with an in situ heating stage. A mixture of the Cu(dedc)₂, Zn(dedc)₂ Sn(dedc)₄ (2:1:1 molar ratio) was heated on the heating stage while collecting data in regular intervals.

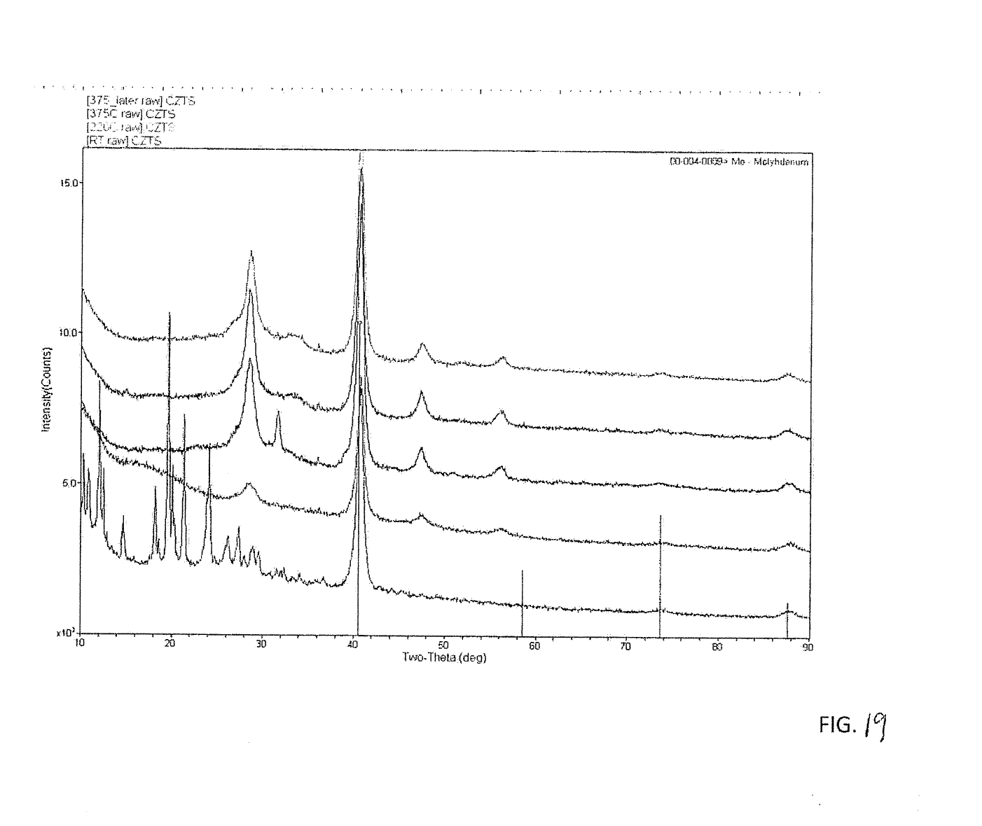

FIG. 19 shows the XRD data collected as a function of time. The bottom XRD pattern in FIG. 19 was collected from the metal complexes at room temperature, before any heating. As the substrate was heated to 220° C., the complexes began to melt and the sharp diffraction peaks between 2θ=10°-30° all disappeared as a consequence of melting and loss of crystalline order. As the complex was heated to higher temperatures the diffraction peaks for Cu₂ZnSnS₄ began to appear and become intense at 375° C. A variety of methods can be used to heat the solution.

### Example 3

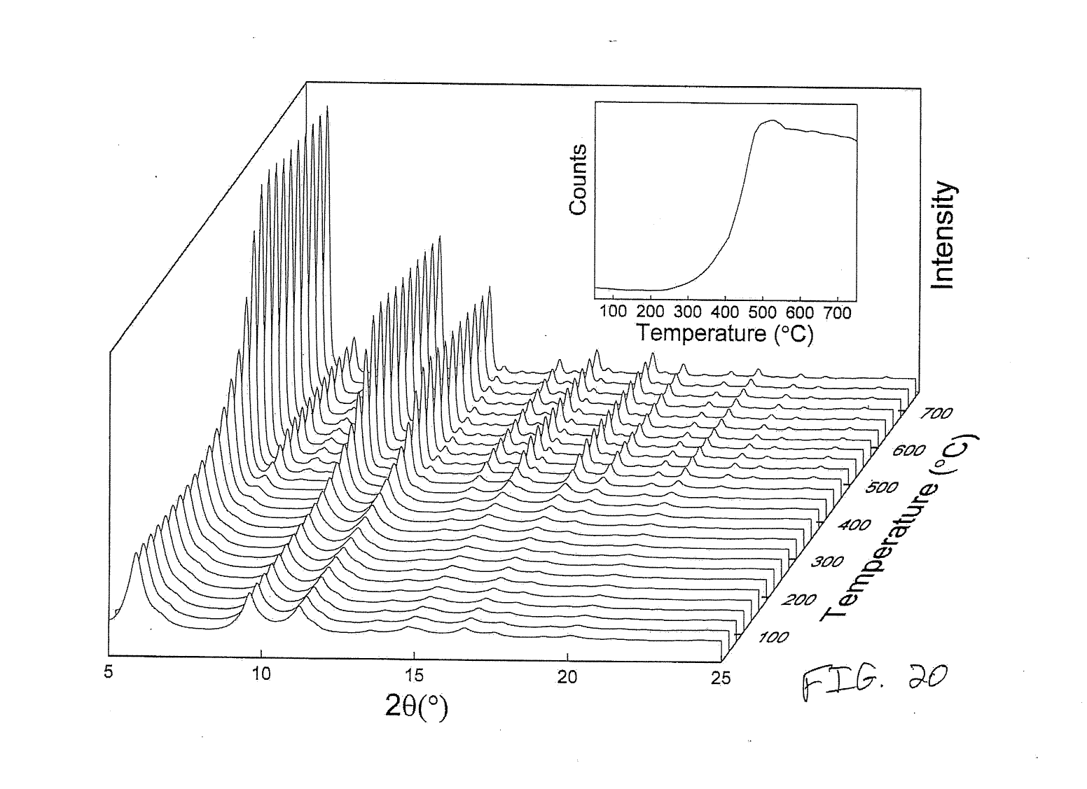

Dried powder of CZTS nanocrystals was heated inside a quartz capillary while it was under examination with X-rays of wavelength 0.3196 Å to monitor the structural changes. FIG. 20 shows the evolution of the X-ray diffraction pattern upon heating. Heating was done in an argon atmosphere at a rate of 10° C./minute. X-ray diffraction from CZTS crystal planes began to rise dramatically starting at approximately 350° C. and was complete when a temperature of 550° C. was reached. Examination of the films treated in this way using rapid thermal annealing showed that the nanocrystals had melted and grown into large grain films.

In summary, the present disclosure illustrates the following embodiments:

### Embodiment 1

A method of preparing a metal chalcogenide comprising heating components comprising: at least one copper, zinc, and/or tin compound selected from the group consisting of chalcogenocarbamates, dichalcogenocarbamates, mercaptides, thiolates, dithiolates, thiocarbonates, dithiocarbonates, trithiocarbonates, and combinations thereof; wherein heating comprises conditions effective to form a compound of the formula Cu_{2+x+z}Zn₁₋ₓSn_{1-z}A₄, wherein A represents one or more chalcogens; −1≦x≦1; −1≦z≦1; and with the proviso that when x=z they are not equal to 1.

### Embodiment 2

The method of embodiment 1 wherein the at least one copper dichalcogenocarbamate is of the formula Cu²⁺(⁻A-(A)C—NR¹R²)₂, wherein each R¹ and R² independently represents H or an organic group in which R¹ and R² can optionally be joined to form one or more rings; and each A independently represents a chalcogen.

### Embodiment 3

The method of embodiment 1 or 2 wherein the at least one zinc dichalcogenocarbamate is of the formula Zn²⁺(⁻A-(A)C—NR¹R²)₂, wherein each R¹ and R² independently represents H or an organic group in which R¹ and R² can optionally be joined to form one or more rings; and each A independently represents a chalcogen.

### Embodiment 4

The method of any one of the preceding embodiments wherein the at least one tin dichalcogenocarbamate is of the formula Sn⁴⁺(⁻A-(A)C—NR¹R²)₄, wherein each R¹ and R² independently represents H or an organic group in which R¹ and R² can optionally be joined to form one or more rings; and each A independently represents a chalcogen.

### Embodiment 5

The method of any one of the preceding embodiments wherein the chalcogen is selected from the group consisting of sulfur, selenium, and combinations thereof.

### Embodiment 6

The method of any one of the preceding embodiments wherein each R¹ and R² independently represents hydrogen or a C1 to C30 aliphatic group.

### Embodiment 7

The method of any one of the preceding embodiments wherein each R¹ and R² independently represents hydrogen or a C1 to C30 aliphatic moiety.

### Embodiment 8

The method of any one of the preceding embodiments wherein x=0, and the compound is of the formula Cu_{2+z}ZnSn_{1-z}S_{y}Se_{4-y}, wherein 0≦y≦4.

### Embodiment 9

The method of embodiment 8 wherein z=0, and the compound is of the formula Cu₂ZnSnS_{y}Se_{4-y}, wherein 0≦y≦4.

### Embodiment 10

The method of embodiment 8 wherein z=1, and the compound is of the formula Cu₃ZnS_{y}Se_{4-y}, wherein 0≦y≦4.

### Embodiment 11

The method of embodiment 8 wherein z=−1, and the compound is of the formula CuZnSn₂S_{y}Se_{4-y}, wherein 0≦y≦4.

### Embodiment 12

The method of any one of embodiments 1 to 7 wherein x=−1, and the compound is of the formula Cu_{1+z}Zn₂Sn_{1-z}S_{y}Se_{4-y}, wherein 0≦y≦4.

### Embodiment 13

The method of embodiment 12 wherein z=0, and the compound is of the formula CuZn₂SnS_{y}Se_{4-y}, wherein 0≦y≦4.

### Embodiment 14

The method of embodiment 12 wherein z=1, and the compound is of the formula Cu₂Zn₂S_{y}Se_{4-y}, wherein 0≦y≦4.

### Embodiment 15

The method of embodiment 12 wherein z=−1, and the compound is of the formula Zn₂Sn₂S_{y}Se_{4-y}, wherein 0≦y≦4.

### Embodiment 16

The method of any one of embodiments 1 to 7 wherein x=1, and the compound is of the formula Cu_{3+z}Sn_{1-z}S_{y}Se_{4-y}, wherein 0≦y≦4.

### Embodiment 17

The method of embodiment 16 wherein z=0, and the compound is of the formula Cu₃SnS_{y}Se_{4-y}, wherein 0≦y≦4.

### Embodiment 18

The method of embodiment 16 wherein z=−1, and the compound is of the formula Cu₂Sn₂SySe_{4-y}, wherein 0≦y≦4.

### Embodiment 19

The method of any one of embodiments 1 to 7 wherein z=0, and the compound is of the formula Cu₂₊ₓZn₁₋ₓSnS_{y}Se_{4-y}, wherein 0≦y≦4.

### Embodiment 20

The method of any one of embodiments 1 to 7 wherein

z=1, and the compound is of the formula Cu₃₊ₓZn₁₋ₓS_{y}Se_{4-y}, wherein 0≦y≦4.

### Embodiment 21

The method of any one of embodiments 1 to 7 wherein z=−1, and the compound is of the formula Cu₁₊ₓZn₁₋ₓSn₂S_{y}Se_{4-y}, wherein 0≦y≦4.

### Embodiment 22

The method of any one of the preceding embodiments wherein conditions effective to form the compound comprise heating the components in the substantial absence of oxygen.

### Embodiment 23

The method of any one of the preceding embodiments wherein conditions effective to form the compound comprise heating the components in a solvent at a temperature of 125° C. to 300° C., and wherein the formed compound is in the form of nanocrystals.

### Embodiment 24

The method of embodiment 23 wherein the nanocrystals have an average particle size of 1 nanometer to 100 nanometers.

### Embodiment 25

The method of embodiment 24 wherein the nanocrystals have an average particle size of 1 nanometer to 20 nanometers.

### Embodiment 26

The method of any one of embodiment 23 to 25 further comprising coating the nanocrystals on a substrate and heating the nanocrystals under conditions effective to form a film of the compound.

### Embodiment 27

The method of embodiment 26 wherein conditions effective to form the film comprise conditions for rapid thermal annealing.

### Embodiment 28

The method of embodiment 26 wherein conditions effective to form the film comprise heating at a temperature below the melting point of the bulk compound.

### Embodiment 29

The method of embodiment 26 wherein heating comprises heating at a temperature of 300° C. to 700° C.

### Embodiment 30

The method of embodiment 29 wherein heating comprises heating at a temperature of 350° C. to 550° C.

### Embodiment 31

The method of embodiment 26 wherein conditions effective to form the film comprise heating for a time of less than or equal to one hour.

### Embodiment 32

The method of embodiment 31 wherein conditions effective to form the film comprise heating for a time of 5 minutes to 15 minutes.

### Embodiment 33

The method of any one of embodiments 1 to 22 wherein the components are applied to a substrate, and wherein conditions effective to form the compound comprise heating the combined components at a temperature of 150° C. to 900° C. to form a film of the compound.

### Embodiment 34

The method of any one of the preceding embodiments wherein conditions effective to form the compound comprise heating in the presence of an amine.

### Embodiment 35

The method of embodiment 34 wherein the amine is selected from the group consisting of oleylamine, dodecylamine, and combinations thereof.

### Embodiment 36

A colloidal dispersion of nanocrystals prepared by a method of any one of embodiments 23 to 25.

### Embodiment 37

The colloidal dispersion of embodiment 36 wherein the dispersion is in the form of a nanocrystal organic ink.

### Embodiment 38

The colloidal dispersion of embodiment 36 wherein the dispersion is in the form of a nanocrystal aqueous ink.

### Embodiment 39

A solar cell comprising: a substrate; and a layer comprising a copper-deficient copper zinc tin chalcogenide over the substrate.

### Embodiment 40

A solar cell comprising: a substrate; and a layer comprising a copper-rich copper zinc tin chalcogenide over the substrate.

### Embodiment 41

A solar cell comprising: a substrate; a layer comprising a copper-deficient copper zinc tin chalcogenide over the substrate; and a layer comprising a copper-rich copper zinc tin chalcogenide over the copper-deficient copper zinc tin chalcogenide layer.

### Embodiment 42

A solar cell comprising: a substrate; a layer comprising a copper-rich copper zinc tin chalcogenide over the substrate; and a layer comprising a copper-deficient copper zinc tin chalcogenide over the copper-rich copper zinc tin chalcogenide layer.

### Embodiment 43

The solar cell of any one of embodiments 40 to 42 wherein the copper-rich copper zinc tin chalcogenide is of the formula Cu₂₊ₓZn₁₋ₓSn S_{y}Se_{4-y}, wherein: 0≦y≦4; and 0<x<1.

### Embodiment 44

The solar cell of any one of embodiments 39, 41, and 42 wherein the copper-deficient copper zinc tin chalcogenide is of the formula Cu₂₊ₓZn₁₋ₓSn S_{y}Se_{4-y}, wherein: 0≦y≦4; and −1<x<0.

### Embodiment 45

The solar cell of any one of embodiments 39 to 44 further comprising a zinc sulfide buffer layer over at least one metal chalcogenide layer or layers.

### Embodiment 46

A method of making a solar cell, the method comprising: preparing a metal chalcogenide by a method according to any one of embodiments 1 to 35; and forming a layer comprising the metal chalcogenide over a substrate.

### Embodiment 47

The method of embodiment 46 further comprising forming a zinc sulfide buffer layer over the metal chalcogenide layer.

### Embodiment 48

The method of embodiment 46 further comprising forming a tin oxide buffer layer over the metal chalcogenide layer.

### Embodiment 49

The method of embodiment 46 further comprising forming a zinc oxide buffer layer over the metal chalcogenide layer.

The complete disclosure of all patents, patent applications, and publications, and electronically available material cited herein are incorporated by reference. The foregoing detailed description and examples have been given for clarity of understanding only. No unnecessary limitations are to be understood therefrom. The invention is not limited to the exact details shown and described, for variations obvious to one skilled in the art will be included within the invention defined by the claims.

1. A method of preparing a metal chalcogenide comprising heating components comprising:
at least one copper, zinc, and/or tin compound selected from the group consisting of chalcogenocarbamates, dichalcogenocarbamates, mercaptides, thiolates, dithiolates, thiocarbonates, dithiocarbonates, trithiocarbonates, and combinations thereof;
wherein heating comprises conditions effective to form a compound of the formula Cu_{2+x+z}Zn₁₋ₓSn_{1-z}A₄, wherein
A represents one or more chalcogens;
−1≦x≦1;
−1≦z≦1; and
with the proviso that when x=z they are not equal to 1.

2. The method of claim 1 wherein the at least one copper dichalcogenocarbamate is of the formula Cu²⁺(⁻A-(A)C—NR¹R²)₂,
wherein each R¹ and R² independently represents H or an organic group in which R¹ and R² can optionally be joined to form one or more rings; and
each A independently represents a chalcogen.

3. The method of claim 1 wherein the at least one zinc dichalcogenocarbamate is of the formula Zn²⁺(⁻A-(A)C—NR¹R²)₂,
wherein each R¹ and R² independently represents H or an organic group in which R¹ and R² can optionally be joined to form one or more rings; and
each A independently represents a chalcogen.

4. The method of claim 1 wherein the at least one tin dichalcogenocarbamate is of the formula Sn⁴⁺(⁻A-(A)C—NR¹R²)₄,
wherein each R¹ and R² independently represents H or an organic group in which R¹ and R² can optionally be joined to form one or more rings; and
each A independently represents a chalcogen.

5. The method of claim 1 wherein the chalcogen is selected from the group consisting of sulfur, selenium, and combinations thereof.

6. The method of claim 1 wherein each R¹ and R² independently represents hydrogen, a C1 to C30 aliphatic group, or a C1 to C30 aliphatic moiety.

7-21. (canceled)

22. The method of claim 1 wherein conditions effective to form the compound comprise heating the components in the substantial absence of oxygen.

23. The method of claim 1 wherein conditions effective to form the compound comprise heating the components in a solvent at a temperature of 125° C. to 300° C., and wherein the formed compound is in the form of nanocrystals.

24. The method of claim 23 wherein the nanocrystals have an average particle size of 1 nanometer to 100 nanometers.

25. (canceled)

26. The method of claim 23 further comprising coating the nanocrystals on a substrate and heating the nanocrystals under conditions effective to form a film of the compound.

27. The method of claim 26 wherein conditions effective to form the film comprise conditions for rapid thermal annealing.

28. The method of claim 26 wherein conditions effective to form the film comprise heating at a temperature below the melting point of the bulk compound.

29. The method of claim 26 wherein heating comprises heating at a temperature of 300° C. to 700° C.

30. (canceled)

31. The method of claim 26 wherein conditions effective to form the film comprise heating for a time of less than or equal to one hour.

32. (canceled)

33. The method of claim 1 wherein the components are applied to a substrate, and wherein conditions effective to form the compound comprise heating the combined components at a temperature of 150° C. to 900° C. to form a film of the compound.

34. The method of claim 1 wherein conditions effective to form the compound comprise heating in the presence of an amine.

35. The method of claim 34 wherein the amine is selected from the group consisting of oleylamine, dodecylamine, and combinations thereof.

36-38. (canceled)

39. A solar cell comprising:
a substrate; and
a layer comprising a copper-deficient copper zinc tin chalcogenide over the substrate, wherein the copper-deficient copper zinc tin chalcogenide is of the formula Cu₂₊ₓZn₁₋ₓSn S_{y}Se_{4-y}, wherein: 0≦y≦4; and −1<x<0.

40. (canceled)

41. The solar cell of claim 39 further comprising a zinc sulfide buffer layer over at least one metal chalcogenide layer or layers.

42. A solar cell comprising:
a substrate; and
a layer comprising a copper-rich copper zinc tin chalcogenide over the substrate, wherein the copper-rich copper zinc tin chalcogenide is of the formula Cu₂₊ₓZn_{1-z}Sn S_{y}Se_{4-y}, wherein: 0≦y≦4; and 0<x<1.

43. (canceled)

44. The solar cell of claim 42 further comprising a zinc sulfide buffer layer over at least one metal chalcogenide layer or layers.

45. A solar cell comprising:
a substrate;
a layer comprising a copper-deficient copper zinc tin chalcogenide over the substrate, wherein the copper-deficient copper zinc tin chalcogenide is of the formula Cu₂₊ₓZn₁₋ₓSn S_{y}Se_{4-y}, wherein: 0≦y≦4; and −1<x<0; and
a layer comprising a copper-rich copper zinc tin chalcogenide over the copper-deficient copper zinc tin chalcogenide layer, wherein the copper-rich copper zinc tin chalcogenide is of the formula Cu₂₊ₓZn₁₋ₓSn S_{y}Se_{4-y}, wherein: 0≦y≦4; and 0<x<1.

46. (canceled)

47. The solar cell of claim 45 further comprising a zinc sulfide buffer layer over at least one metal chalcogenide layer or layers.

48. A solar cell comprising:
a substrate;
a layer comprising a copper-rich copper zinc tin chalcogenide over the substrate, wherein the copper-rich copper zinc tin chalcogenide is of the formula Cu₂₊ₓZn₁₋ₓSn S_{y}Se_{4-y}, wherein: 0≦y≦4; and 0<x<1; and
a layer comprising a copper-deficient copper zinc tin chalcogenide over the copper-rich copper zinc tin chalcogenide layer, wherein the copper-deficient copper zinc tin chalcogenide is of the formula Cu₂₊ₓZn₁₋ₓSn S_{y}Se_{4-y}, wherein: 0≦y≦4; and −1<x<0.

49. (canceled)

50. The solar cell of claim 48 further comprising a zinc sulfide buffer layer over at least one metal chalcogenide layer or layers.

51. A method of making a solar cell, the method comprising:
preparing a metal chalcogenide by a method according to claim 1;
forming a layer comprising the metal chalcogenide over a substrate; and
forming a zinc sulfide buffer layer, a tin oxide buffer layer, or a zinc oxide buffer layer over the metal chalcogenide layer.

52-54. (canceled)
